(19) United States
(12) Patent Application Publication
(10) Pub. No.: US 2025/0254911 A1
(43) Pub. Date: Aug. 7, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wu-Wei TSAI, Hsinchu (TW); Yan-Yi CHEN, Hsinchu (TW); Yin-Hao WU, Hsinchu (TW); Hai-Ching CHEN, Hsinchu (TW)

(73) Assignee: Taiwan Semiconductor Manufacturing Company, Ltd., Hsinchu (TW)

(21) Appl. No.: 18/433,033

(22) Filed: Feb. 5, 2024

(51) Int. Cl. H01L 29/786; H01L 29/66

(52) U.S. Cl. CPC H10D 30/6704; H10D 30/6755; H10D 99/00

(57) ABSTRACT

A semiconductor device includes a FEOL structure and a transistor. The transistor is disposed on the FEOL structure and includes a back gate, an active channel layer, an electrode, a dielectric layer and a first blocking layer. The back gate is disposed on the FEOL structure. The active channel layer is disposed on the back gate. The electrode electrically is connected to the active channel layer. The dielectric layer is disposed over the active channel layer. The first blocking layer is disposed on the dielectric layer and overlaps the active channel layer.

### BACKGROUND

A semiconductor device may include at least one transistor, and the transistor includes an active channel layer. However, after the active channel layer is formed, the active channel layer is easy to be polluted in subsequent manufacturing processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor device according to an embodiment of the present disclosure;

FIG. 2 illustrates a schematic diagram of a cross-sectional view of a semiconductor device according to another embodiment of the present disclosure;

FIG. 3 illustrates a schematic diagram of a cross-sectional view of a semiconductor device according to another embodiment of the present disclosure;

FIG. 4 illustrates a schematic diagram of a cross-sectional view of a semiconductor device according to another embodiment of the present disclosure;

FIG. 5 illustrates a schematic diagram of a cross-sectional view of a semiconductor device according to another embodiment of the present disclosure;

FIG. 6 illustrates a schematic diagram of a cross-sectional view of a semiconductor device according to another embodiment of the present disclosure;

FIG. 7 illustrates a schematic diagram of a cross-sectional view of a semiconductor device according to another embodiment of the present disclosure;

FIGS. 8A to 8E illustrate schematic diagrams of manufacturing processes of the semiconductor device in FIG. 1;

FIGS. 9A to 9F illustrate schematic diagrams of manufacturing processes of the semiconductor device in FIG. 2;

FIGS. 10A to 10E illustrate schematic diagrams of manufacturing processes of the semiconductor device in FIG. 3;

FIGS. 11A to 11F illustrate schematic diagrams of manufacturing processes of the semiconductor device in FIG. 4;

FIGS. 12A to 12F illustrate schematic diagrams of manufacturing processes of the semiconductor device in FIG. 5;

FIGS. 13A to 13F illustrate schematic diagrams of manufacturing processes of the semiconductor device in FIG. 6;

FIGS. 14A to 14G illustrate schematic diagrams of manufacturing processes of the semiconductor device in FIG. 7;

FIG. 15 illustrates a schematic diagram of a cross-sectional view of a semiconductor device according to an embodiment of the present disclosure;

FIG. 16 illustrates a schematic diagram of a cross-sectional view of a semiconductor device according to another embodiment of the present disclosure;

FIG. 17 illustrates a schematic diagram of a cross-sectional view of a semiconductor device according to another embodiment of the present disclosure;

FIG. 18 illustrates a schematic diagram of a cross-sectional view of a semiconductor device according to another embodiment of the present disclosure;

FIG. 19 illustrates a schematic diagram of a cross-sectional view of a semiconductor device according to another embodiment of the present disclosure;

FIG. 20 illustrates a schematic diagram of a cross-sectional view of a semiconductor device according to another embodiment of the present disclosure;

FIGS. 21A to 21F illustrate schematic diagrams of manufacturing processes of the semiconductor device in FIG. 15;

FIGS. 22A to 22G illustrate schematic diagrams of manufacturing processes of the semiconductor device in FIG. 16;

FIGS. 23A to 23G illustrate schematic diagrams of manufacturing processes of the semiconductor device in FIG. 17;

FIGS. 24A to 24G illustrate schematic diagrams of manufacturing processes of the semiconductor device in FIG. 18;

FIGS. 25A to 25H illustrate schematic diagrams of manufacturing processes of the semiconductor device in FIG. 19; and

FIGS. 26A to 26G illustrate schematic diagrams of manufacturing processes of the semiconductor device in FIG. 20.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

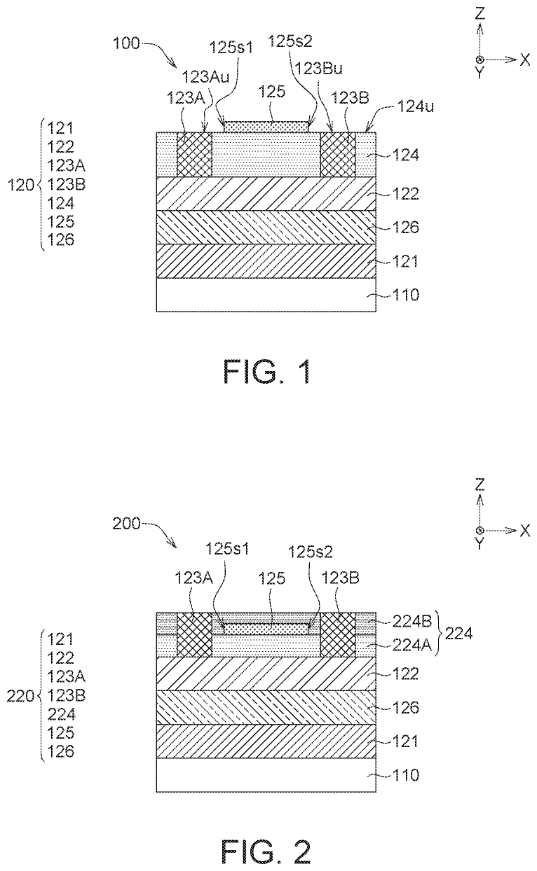

Referring to FIG. 1, FIG. 1 illustrates a schematic diagram of a cross-sectional view of a semiconductor device 100 according to an embodiment of the present disclosure. The semiconductor device 100 may include a FEOL (Front End of Line) structure 110 and at least one transistor 120. The transistor 120 is formed on the FEOL structure 110 and includes a back gate 121, an active channel layer 122, at least electrode (for example, a first electrode 123A and a second electrode 123B), a dielectric layer 124, a first blocking layer 125 and a dielectric layer 126. The back gate 121 is formed on the FEOL structure 110. The active channel layer 122 is formed above the back gate 121. The electrodes are electrically connected to the active channel layer 122. The dielectric layer 124 is formed over the active channel layer 122. The first blocking layer 125 is formed in the dielectric layer 124 and overlaps the active channel layer 122 in a stacking direction (for example, Z-axis) of the first blocking layer 125 and the active channel layer 122. The first blocking layer 125 may block the gas and/or impurities from entering the active channel layer 122 in manufacturing process.

As illustrated in FIG. 1, the transistor 120 is, for example, formed in a BEOL (Back End of Line) structure. Though not illustrated, the semiconductor device 100 may further include a MEOL (Middle End of Line) structure formed between the BEOL structure and the FEOL structure 110.

As illustrated in FIG. 1, the back gate 121 may be formed of, for example, metal. In an embodiment, the active channel layer 122 is, for example, an oxide-semiconductor (OS) layer. In an embodiment, the active channel layer 122 may be formed of a material including, for example, CuO, SnO, InO, IZO, IGO, IGZO, IWO, IWZO, etc. The first electrode 123A is, for example, one of a source and a drain of the transistor 120, and the second electrode 123B is, for example, another of the source and the drain of the transistor 120. The dielectric layer 124 is, for example, an ILD (Inter-Layer Dielectric), and formed on the active channel layer 122. In an embodiment, the dielectric layer 124 may be formed of a material including, for example, SiOx, SiNx, HfSiOx, etc. The first electrode 123A and the second electrode 123B are formed within the dielectric layer 124 and connected with the active channel layer 122. In the present embodiment, the first blocking layer 125 is formed on the dielectric layer 124.

As illustrated in FIG. 1, the dielectric layer 124 has a first upper surface 124u, the first electrode 123A has a second upper surface 123Au, and the second electrode 123B has a second upper surface 123Bu, wherein the first upper surface 124u, the second upper surface 123Au and the second upper surface 123Bu are flush with each other. The first blocking layer 125 is formed on the first upper surface 124u of the dielectric layer 124.

In an embodiment, the first blocking layer 125 may be formed of an insulation material or a conductive material including, for example, AlOx, HfOx, InO, CuO, SnO, InO, IZO, IGO, IGZO, IWO, IWZO, etc. The dielectric layer 126 may be formed between the back gate 121 and the active channel layer 122. In an embodiment, the dielectric layer 126 may be formed of a material including, for example, SiO₂, Al₂O₃, HfO, HfO:ZrO, HfO:Al₂O₃, HfO:La₂O₃, HfO:SiO₂, HfO:SrO, etc.

As illustrated in FIG. 1, the first blocking layer 125 has a first lateral surface 125s1 and a second lateral surface 125s2, wherein the first lateral surface 125s1 of the first blocking layer 125 may be spaced from a lateral surface of the first electrode 123A by a distance in X-axis, and the second lateral surface 125s2 of the first blocking layer 125 may be spaced from a lateral surface of the second electrode 123B by a distance in X-axis. In another embodiment, the first blocking layer 125 may be formed of the insulation material, and the first lateral surface 125s1 may be aligned with the lateral surface of the first electrode 123A or overlaps the lateral surface of the first electrode 123A in Z-axis, and/or the second lateral surface 125s2 may be aligned with the lateral surface of the second electrode 123B or overlaps the lateral surface of the second electrode 123B in Z-axis.

Referring to FIG. 2, FIG. 2 illustrates a schematic diagram of a cross-sectional view of a semiconductor device 200 according to another embodiment of the present disclosure. The semiconductor device 200 may include the FEOL structure 110 and at least one transistor 220. The transistor 220 is formed on the FEOL structure 110 and includes the back gate 121, the active channel layer 122, at least electrode (for example, the first electrode 123A and the second electrode 123B), a dielectric layer 224, the first blocking layer 125 and the dielectric layer 126. The back gate 121 is formed on the FEOL structure 110. The active channel layer 122 is formed above the back gate 121. The electrodes are electrically connected to the active channel layer 122. The dielectric layer 224 is formed over the active channel layer 122. The first blocking layer 125 is formed within the dielectric layer 224. The first blocking layer 125 may block the gas and/or impurities from entering the active channel layer 122 in manufacturing process.

As illustrated in FIG. 2, the transistor 220 is, for example, formed in the BEOL structure. Though not illustrated, the semiconductor device 200 may further include the MEOL structure formed between the BEOL structure and the FEOL structure 110.

As illustrated in FIG. 2, the back gate 121 may be formed of, for example, metal. In an embodiment, the active channel layer 122 is, for example, the OS layer. The first electrode 123A is, for example, one of a source and a drain of the transistor 120, and the second electrode 123B is, for example, another of the source and the drain of the transistor 120.

As illustrated in FIG. 2, the dielectric layer 224 is a multi-layered structure. Furthermore, the dielectric layer 224 includes a first sub-dielectric layer 224A and a second sub-dielectric layer 224B, wherein the first sub-dielectric layer 224A is formed on the active channel layer 122, and the second sub-dielectric layer 224B is formed on the first sub-dielectric layer 224A and covers the first blocking layer 125. The first blocking layer 125 is formed between the first sub-dielectric layer 224A and the second sub-dielectric layer 224B. Furthermore, the first blocking layer 125 is formed above the first sub-dielectric layer 224A and covered by the second sub-dielectric layer 224B.

The dielectric layer 224 is, for example, an ILD layer, and formed on the active channel layer 122. In an embodiment, the dielectric layer 224 may be formed of a material including, for example, SiOx, SiNx, HfSiOx, etc. The first electrode 123A and the second electrode 123B are formed within the dielectric layer 224 and connected with the active channel layer 122. In the present embodiment, the first blocking layer 125 is formed within the dielectric layer 224. The dielectric layer 126 may be formed between the back gate 121 and the active channel layer 122.

As illustrated in FIG. 2, the first blocking layer 125 has the first lateral surface 125s1 and the second lateral surface 125s2, wherein the first lateral surface 125s1 of the first blocking layer 125 may be spaced from the lateral surface of the first electrode 123A by a distance in X-axis, and the second lateral surface 125s2 of the first blocking layer 125 may be spaced from the lateral surface of the second electrode 123B by a distance in X-axis. In another embodiment, the first blocking layer 125 may be formed of the insulation material, and the first lateral surface 125s1 may be contact with the lateral surface of the first electrode 123A, and/or the second lateral surface 125s2 may be contact with the lateral surface of the second electrode 123B.

Referring to FIG. 3, FIG. 3 illustrates a schematic diagram of a cross-sectional view of a semiconductor device 300 according to another embodiment of the present disclosure. The semiconductor device 300 may include the FEOL structure 110 and at least one transistor 320. The transistor 320 is formed on the FEOL structure 110 and includes the back gate 121, the active channel layer 122, at least electrode (for example, the first electrode 123A and the second electrode 123B), the dielectric layer 124, a first blocking layer 325 and the dielectric layer 126. The back gate 121 is formed on the FEOL structure 110. The active channel layer 122 is formed above the back gate 121. The electrodes are electrically connected to the active channel layer 122. The dielectric layer 124 is formed over the active channel layer 122. In the present embodiment, the first blocking layer 325 is formed within the dielectric layer 124. Furthermore, the first blocking layer 325 is formed on the active channel layer 122 and covered by the dielectric layer 124. The first blocking layer 325 may block the gas and/or impurities from entering the active channel layer 122 in manufacturing process.

As illustrated in FIG. 3, the transistor 320 is, for example, formed in the BEOL structure. Though not illustrated, the semiconductor device 300 may further include the MEOL structure formed between the BEOL structure and the FEOL structure 110.

As illustrated in FIG. 3, the first blocking layer 325 is in contact with the active channel layer 122 and may be formed of a high dielectric constant material including, for example, AlOx, HfOx, InO, CuO, SnO, InO, IZO, IGO, IGZO, IWO, IWZO, etc.

As illustrated in FIG. 3, the first blocking layer 325 has a first lateral surface 325s1 and a second lateral surface 325s2, wherein the first lateral surface 325s1 of the first blocking layer 325 may be spaced from the lateral surface of the first electrode 123A by a distance in X-axis, and the second lateral surface 325s2 of the first blocking layer 325 may be spaced from the lateral surface of the second electrode 123B by a distance in X-axis. In another embodiment, the first lateral surface 325s1 may be contact with the lateral surface of the first electrode 123A, and/or the second lateral surface 325s2 may be contact with the lateral surface of the second electrode 123B.

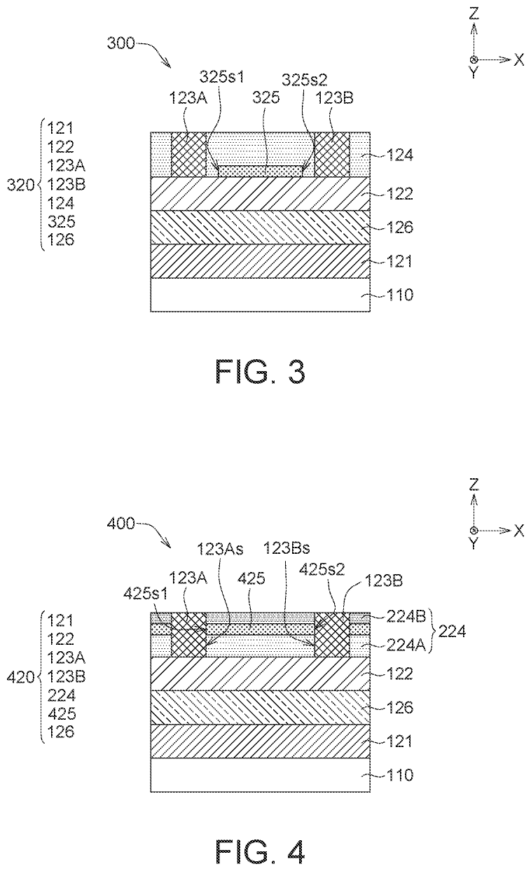

Referring to FIG. 4, FIG. 4 illustrates a schematic diagram of a cross-sectional view of a semiconductor device 400 according to another embodiment of the present disclosure. The semiconductor device 400 may include the FEOL structure 110 and at least one transistor 420. The transistor 420 is formed on the FEOL structure 110 and includes the back gate 121, the active channel layer 122, at least electrode (for example, the first electrode 123A and the second electrode 123B), the dielectric layer 224, a first blocking layer 425 and the dielectric layer 126. The back gate 121 is formed on the FEOL structure 110. The active channel layer 122 is formed above the back gate 121. The electrodes are electrically connected to the active channel layer 122. The dielectric layer 224 is formed over the active channel layer 122. The first blocking layer 425 is formed within the dielectric layer 224. The first blocking layer 425 may block the gas and/or impurities from entering the active channel layer 122 in manufacturing process.

As illustrated in FIG. 4, the transistor 420 is, for example, formed in the BEOL structure. Though not illustrated, the semiconductor device 400 may further include the MEOL structure formed between the BEOL structure and the FEOL structure 110.

As illustrated in FIG. 4, the first blocking layer 425 is formed within the dielectric layer 224. Furthermore, the first blocking layer 425 is formed on the first sub-dielectric layer 224A and covered by the second sub-dielectric layer 224B. The first sub-dielectric layer 224A and the second sub-dielectric layer 224B may be formed of a material including, for example, SiOx, SiNx, HfSiOx, etc. In the present embodiment, the first blocking layer 425 may extend to the first electrode 123A and the second electrode 123B. Furthermore, the first blocking layer 425 has a first lateral surface 425s1 and a second lateral surface 425s2, the first electrode 123A has an electrode lateral surface 123As, and the second electrode 123B has an electrode lateral surface 123Bs, wherein the first lateral surface 425s1 is contact with the electrode lateral surface 123As, and the second lateral surface 425s2 is contact with the electrode lateral surface 123Bs. As a result, most of the active channel layer 122 may be covered/protected by the first blocking layer 425. In addition, the first blocking layer 425 is formed within the dielectric layer 224. In the present embodiment, the first blocking layer 425 may be formed of an insulation material including, for example, AlOx, NbOx, etc. As a result, the first blocking layer 425 may electrically isolate the first electrode 123A from the second electrode 123B.

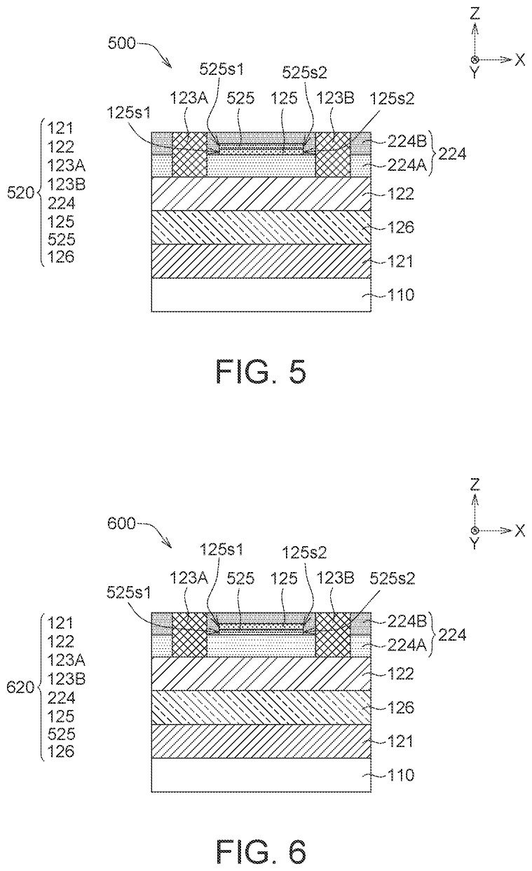

Referring to FIG. 5, FIG. 5 illustrates a schematic diagram of a cross-sectional view of a semiconductor device 500 according to another embodiment of the present disclosure. The semiconductor device 500 may include the FEOL structure 110 and at least one transistor 520. The transistor 520 is formed on the FEOL structure 110 and includes the back gate 121, the active channel layer 122, at least electrode (for example, the first electrode 123A and the second electrode 123B), the dielectric layer 224, the first blocking layer 125, the dielectric layer 126 and a second blocking layer 525. The back gate 121 is formed on the FEOL structure 110. The active channel layer 122 is formed above the back gate 121. The electrodes are electrically connected to the active channel layer 122. The dielectric layer 224 is formed over the active channel layer 122. The first blocking layer 125 and the second blocking layer 525 are formed within the dielectric layer 224. In the present embodiment, the second blocking layer 525 is formed above the first blocking layer 125 and overlaps the active channel layer 122. The first blocking layer 125 and the second blocking layer 525 may block the gas and/or impurities from entering the active channel layer 122 in manufacturing process.

As illustrated in FIG. 5, the transistor 520 is, for example, formed in the BEOL structure. Though not illustrated, the semiconductor device 500 may further include the MEOL structure formed between the BEOL structure and the FEOL structure 110.

As illustrated in FIG. 5, the dielectric layer 224 is a multi-layered structure. Furthermore, the dielectric layer 224 includes the first sub-dielectric layer 224A and the second sub-dielectric layer 224B. The first sub-dielectric layer 224A is formed on the active channel layer 122, and the second sub-dielectric layer 224B is formed on the first sub-dielectric layer 224A. The first blocking layer 125 and the second blocking layer 525 are formed between the first sub-dielectric layer 224A and the second sub-dielectric layer 224B. Furthermore, the first blocking layer 125 and the second blocking layer 525 are formed above the first sub-dielectric layer 224A and covered by the second sub-dielectric layer 224B. In addition, the first blocking layer 125 is contact with the second blocking layer 525.

As illustrated in FIG. 5, the first blocking layer 125 and the second blocking layer 525 may be formed of different material. For example, the first blocking layer 125 may be formed of a high dielectric constant material including, for example, AlOx, HfOx, etc., and the second blocking layer 525 may be formed of an oxide semiconductor material including, for example, CuO, SnO, InO, IZO, IGO, IGZO, IWO, IWZO, etc.

As illustrated in FIG. 5, in the present embodiment, the second blocking layer 525 and the first blocking layer 125 vertically overlap. The entirety of the second blocking layer 525 may overlap the first blocking layer 125. In another embodiment, the second blocking layer 525 may cover an upper surface and at least one lateral surface of the first blocking layer 125. In another embodiment, the second blocking layer 525 covers a portion of an upper surface of the first blocking layer 125, and another portion of the upper surface of the first blocking layer 125 is exposed from the second blocking layer 525.

As illustrated in FIG. 5, the first blocking layer 125 has the first lateral surface 125s1 and the second lateral surface 125s2, wherein the first lateral surface 325s1 of the first blocking layer 325 may be spaced from the lateral surface of the first electrode 123A by a distance in X-axis, and the second lateral surface 125s2 of the first blocking layer 125 may be spaced from the lateral surface of the second electrode 123B by a distance in X-axis. In another embodiment, the first blocking layer 125 may formed of an insulation material, wherein the first lateral surface 125s1 may be contact with the lateral surface of the first electrode 123A, and/or the second lateral surface 125s2 may be contact with the lateral surface of the second electrode 123B. The second blocking layer 525 has a third lateral surface 525s1 and a fourth second lateral surface 525s2, wherein the third lateral surface 525s1 of the second blocking layer 525 may be spaced from the lateral surface of the first electrode 123A by a distance in X-axis, and the fourth lateral surface 525s2 of the second blocking layer 525 may be spaced from the lateral surface of the second electrode 123B by a distance in X-axis. In another embodiment, the second blocking layer 525 may formed of an insulation material, wherein the third lateral surface 525s1 may be contact with the lateral surface of the first electrode 123A, and/or the fourth lateral surface 525s2 may be contact with the lateral surface of the second electrode 123B. In the present embodiment, the first lateral surface 125s1 may be aligned with the third lateral surface 525s1, and the second lateral surface 125s2 may be aligned with the fourth lateral surface 525s2. In another embodiment, the first lateral surface 125s1 may be spaced from the third lateral surface 525s1 by a distance in X axis, and the second lateral surface 125s2 may be spaced from the fourth lateral surface 525s2 by a distance in X axis.

Referring to FIG. 6, FIG. 6 illustrates a schematic diagram of a cross-sectional view of a semiconductor device 600 according to another embodiment of the present disclosure. The semiconductor device 600 may include the FEOL structure 110 and at least one transistor 620. The transistor 620 is formed on the FEOL structure 110 and includes the back gate 121, the active channel layer 122, at least electrode (for example, the first electrode 123A and the second electrode 123B), the dielectric layer 224, the first blocking layer 125, the dielectric layer 126 and the second blocking layer 525. The back gate 121 is formed on the FEOL structure 110. The active channel layer 122 is formed above the back gate 121. The electrodes are electrically connected to the active channel layer 122. The dielectric layer 224 is formed over the active channel 122. The first blocking layer 125 and the second blocking layer 525 are formed within the dielectric layer 224. In the present embodiment, the second blocking layer 525 is formed below the first blocking layer 125 and overlaps the active channel layer 122. The first blocking layer 125 and the second blocking layer 525 may block the gas and/or impurities from entering the active channel layer 122 in manufacturing process.

As illustrated in FIG. 6, the transistor 620 is, for example, formed in the BEOL structure. Though not illustrated, the semiconductor device 600 may further include the MEOL structure formed between the BEOL structure and the FEOL structure 110.

As illustrated in FIG. 6, the first blocking layer 125 and the second blocking layer 525 are formed between the first sub-dielectric layer 224A and the second sub-dielectric layer 224B. Furthermore, the first blocking layer 125 and the second blocking layer 525 are formed above the first sub-dielectric layer 224A and covered by the second sub-dielectric layer 224B. Furthermore, the second blocking layer 525 is formed on the first sub-dielectric layer 224A and the first blocking layer 125 is formed on and above the second blocking layer 525.

As illustrated in FIG. 6, in the present embodiment, the second blocking layer 525 and the first blocking layer 125 vertically overlap. The entirety of the first blocking layer 125 may overlap the second blocking layer 525. In another embodiment, the first blocking layer 125 may cover an upper surface and at least one lateral surface of the second blocking layer 525. In another embodiment, the first blocking layer 125 covers a portion of an upper surface of the second blocking layer 525, and another portion of the upper surface of the second blocking layer 525 is exposed from the first blocking layer 125.

As illustrated in FIG. 6, the first blocking layer 125 has the first lateral surface 125s1 and the second lateral surface 125s2, wherein the first lateral surface 325s1 of the first blocking layer 325 may be spaced from the lateral surface of the first electrode 123A by a distance in X-axis, and the second lateral surface 125s2 of the first blocking layer 125 may be spaced from the lateral surface of the second electrode 123B by a distance in X-axis. In another embodiment, the first blocking layer 125 may formed of an insulation material, wherein the first lateral surface 125s1 may be contact with the lateral surface of the first electrode 123A, and/or the second lateral surface 125s2 may be contact with the lateral surface of the second electrode 123B. The second blocking layer 525 has the third lateral surface 525s1 and the fourth second lateral surface 525s2, wherein the third lateral surface 525s1 of the second blocking layer 525 may be spaced from the lateral surface of the first electrode 123A by a distance in X-axis, and the fourth lateral surface 525s2 of the second blocking layer 525 may be spaced from the lateral surface of the second electrode 123B by a distance in X-axis. In another embodiment, the second blocking layer 525 may formed of an insulation material, wherein the third lateral surface 525s1 may be contact with the lateral surface of the first electrode 123A, and/or the fourth lateral surface 525s2 may be contact with the lateral surface of the second electrode 123B. In the present embodiment, the first lateral surface 125s1 may be aligned with the third lateral surface 525s1, and the second lateral surface 125s2 may be aligned with the fourth lateral surface 525s2. In another embodiment, the first lateral surface 125s1 may be spaced from the third lateral surface 525s1 by a distance in X axis, and the second lateral surface 125s2 may be spaced from the fourth lateral surface 525s2 by a distance in X axis.

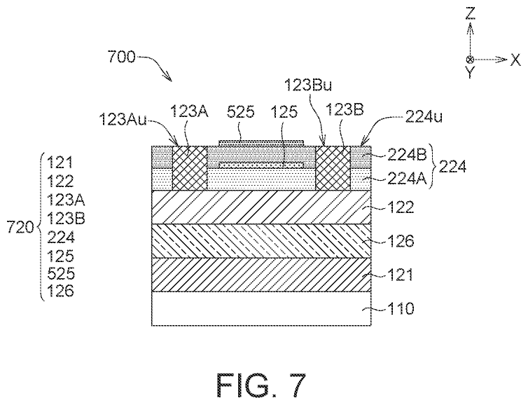

Referring to FIG. 7, FIG. 7 illustrates a schematic diagram of a cross-sectional view of a semiconductor device 700 according to another embodiment of the present disclosure. The semiconductor device 700 may include the FEOL structure 110 and at least one transistor 720. The transistor 720 is formed on the FEOL structure 110 and includes the back gate 121, the active channel layer 122, at least electrode (for example, the first electrode 123A and the second electrode 123B), the dielectric layer 224, the first blocking layer 125, the dielectric layer 126 and a second blocking layer 525. The back gate 121 is formed on the FEOL structure 110. The active channel layer 122 is formed above the back gate 121. The electrodes are electrically connected to the active channel layer 122. The dielectric layer 224 is formed over the active channel 122. The first blocking layer 125 is formed within the dielectric layer 224, and the second blocking layer 525 is formed on the second sub-dielectric layer 224B. The first blocking layer 125 and the second blocking layer 525 may block the gas and/or impurities from entering the active channel layer 122 in manufacturing process.

As illustrated in FIG. 7, the transistor 720 is, for example, formed in the BEOL structure. Though not illustrated, the semiconductor device 700 may further include the MEOL structure formed between the BEOL structure and the FEOL structure 110.

As illustrated in FIG. 7, the dielectric layer 224 is a multi-layered structure. Furthermore, the dielectric layer 224 includes the first sub-dielectric layer 224A and the second sub-dielectric layer 224B. The first sub-dielectric layer 224A is formed on the active channel layer 122, and the second sub-dielectric layer 224B is formed on the first sub-dielectric layer 224A. The dielectric layer 224 has a first upper surface 224u, the first electrode 123A has the second upper surface 123Au, and the second electrode 123B has the second upper surface 123Bu, wherein the first upper surface 224u, the second upper surface 123Au and the second upper surface 123Bu are flush with each other. One of the first blocking layer 125 and the second blocking layer 525 may be formed on the first upper surface 224u.

In the present embodiment, the first blocking layer 125 is formed on the first sub-dielectric layer 224A, and the second blocking layer 525 is formed on the second sub-dielectric layer 224B. The first blocking layer 125 and the second blocking layer 525 may be separated from each other by the second sub-dielectric layer 224B.

In addition, the first blocking layer 125 of each of the semiconductor devices 100, 200, 300, 500, 600 and 700 may be replaced by the first blocking layer 425 of the semiconductor device 400. In another embodiment, the second blocking layer 525 may include the feature the same as or similar to that of the first blocking layer 425.

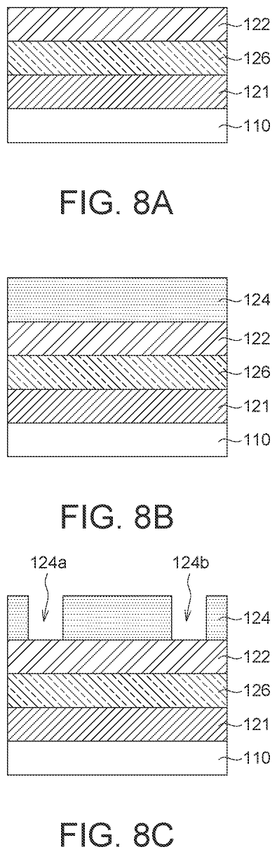

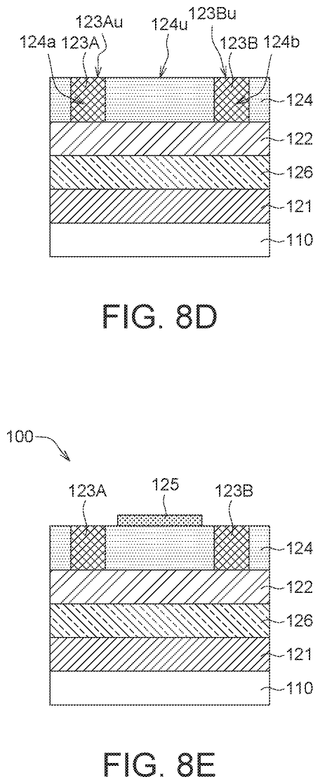

Referring to FIGS. 8A to 8E, FIGS. 8A to 8E illustrate schematic diagrams of manufacturing processes of the semiconductor device 100 in FIG. 1.

As illustrated in FIG. 8A, the back gate 121, the dielectric layer 126 and the active channel layer 122 are formed on the FEOL structure 110 in order by using, for example, deposition, etc.

As illustrated in FIG. 8B, the dielectric layer 124 is formed on the active channel layer 122 by using, for example, deposition, etc.

As illustrated in FIG. 8C, the dielectric layer 124 in FIG. 8B is patterned to form a first through hole 124a and a second through hole 124b exposing the active channel layer 122 by using, for example, photolithography (at least including exposure, development and/or etching, etc.), etc.

As illustrated in FIG. 8D, the first electrode 123A and the second electrode 123B connected with the active channel layer 122 are formed within the first through hole 124a and the second through hole 124b respectively by using, for example, deposition, electroplating, etc. Then, the first electrode 123A, the second electrode 123B and the dielectric layer 124 may be planarized by using, for example, a CMP (Chemical-Mechanical Planarization). After CMP, the first electrode 123A has the second upper surface 123Au, the second electrode 123B has the second upper surface 123Bu and the dielectric layer 124 has the first upper surface 124u, wherein the second upper surface 123Au, the second upper surface 123Bu and the first upper surface 124u are flushed with each other.

As illustrated in FIG. 8E, the first blocking layer 125 is formed on the dielectric layer 124 by using, for example, deposition, photolithography, etc. So far, the semiconductor device 100 in FIG. 1 is formed.

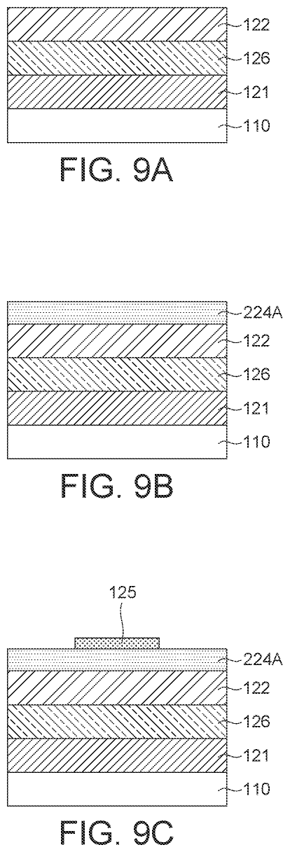

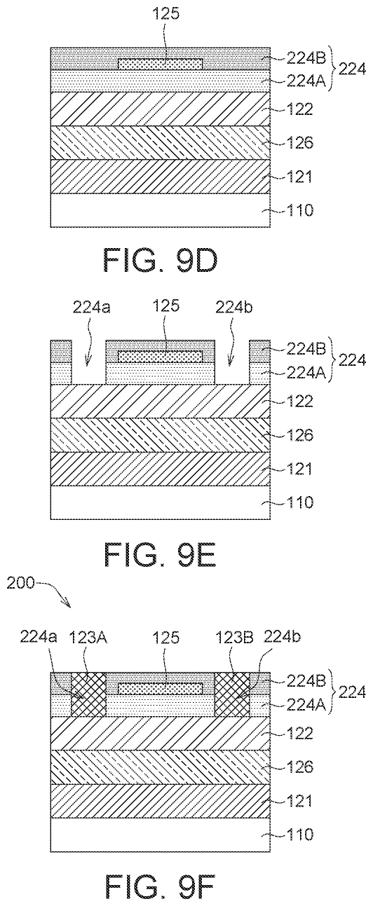

Referring to FIGS. 9A to 9F, FIGS. 9A to 9F illustrate schematic diagrams of manufacturing processes of the semiconductor device 200 in FIG. 2.

As illustrated in FIG. 9A, the back gate 121, the dielectric layer 126 and active channel layer 122 are formed on the FEOL structure 110 in order by using, for example, deposition, etc.

As illustrated in FIG. 9B, the first sub-dielectric layer 224A is formed on the active channel layer 122 by using, for example, deposition, etc. In an embodiment, the first sub-dielectric layer 224A may be planarized by using, for example, a CMP.

As illustrated in FIG. 9C, the first blocking layer 125 is formed on the first sub-dielectric layer 224A by using, for example, deposition, photolithography, etc.

As illustrated in FIG. 9D, the second sub-dielectric layer 224B covering the first blocking layer 125 is formed on the first sub-dielectric layer 224A by using, for example, deposition, etc. The second sub-dielectric layer 224B and the first sub-dielectric layer 224A may form the dielectric layer 224.

As illustrated in FIG. 9E, the dielectric layer 224 in FIG. 9D is patterned to form a first through hole 224a and a second through hole 224b passing through the second sub-dielectric layer 224B and the first sub-dielectric layer 224A and exposing the active channel layer 122 by using, for example, photolithography, etc.

As illustrated in FIG. 9F, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 200 in FIG. 2 is formed.

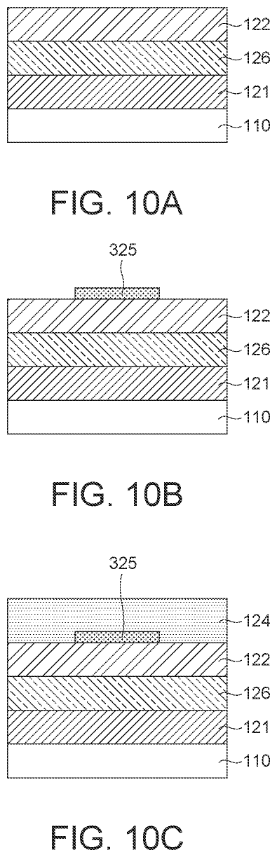

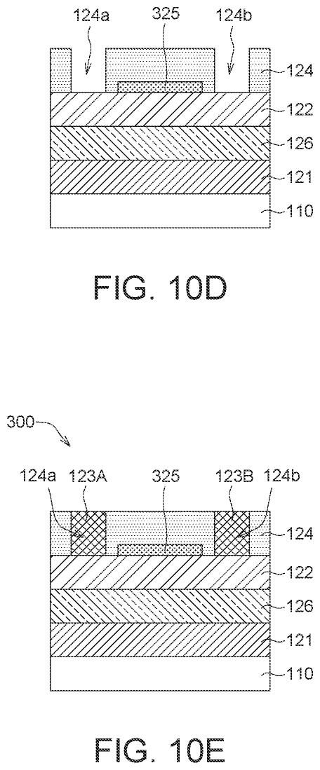

Referring to FIGS. 10A to 10E, FIGS. 10A to 10E illustrate schematic diagrams of manufacturing processes of the semiconductor device 300 in FIG. 3.

As illustrated in FIG. 10A, the back gate 121, the dielectric layer 126 and the active channel layer 122 are formed on the FEOL structure 110 in order by using, for example, deposition, etc. In an embodiment, the active channel layer 122 may be planarized by using, for example, a CMP.

As illustrated in FIG. 10B, the first blocking layer 325 is formed on the active channel layer 122 by using, for example, deposition, photolithography, etc.

As illustrated in FIG. 10C, the dielectric layer 124 covering the first blocking layer 325 is formed by using, for example, deposition, etc.

As illustrated in FIG. 10D, the dielectric layer 124 in FIG. 10C is patterned to form the first through hole 124a and the second through hole 124b passing through the dielectric layer 124 and exposing the active channel layer 122 by using, for example, photolithography, etc.

As illustrated in FIG. 10E, the first electrode 123A and the second electrode 123B connected with the active channel layer 122 are formed within the first through hole 124a and the second through hole 124b respectively by using, for example, deposition, electroplating, etc. Then, the first electrode 123A, the second electrode 123B and the dielectric layer 124 may be planarized by using, for example, a CMP. So far, the semiconductor device 300 in FIG. 3 is formed.

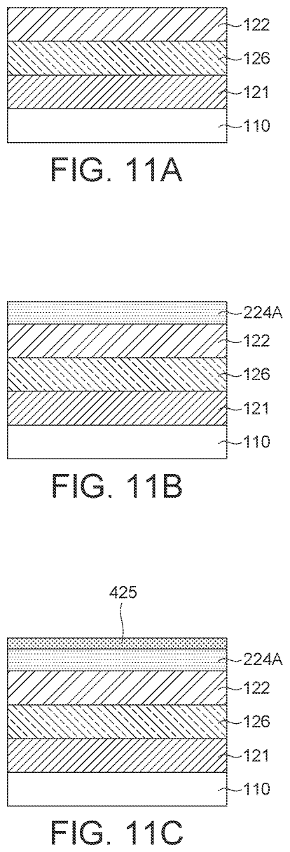

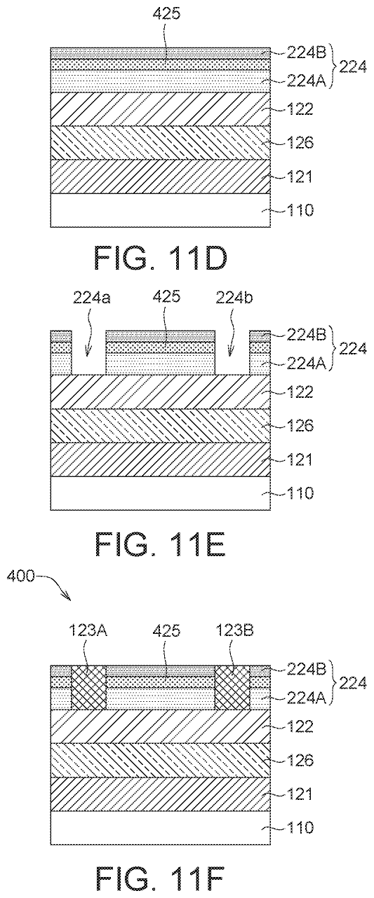

Referring to FIGS. 11A to 11F, FIGS. 11A to 11F illustrate schematic diagrams of manufacturing processes of the semiconductor device 400 in FIG. 4.

As illustrated in FIG. 11A, the back gate 121, the dielectric layer 126 and active channel layer 122 are formed on the FEOL structure 110 in order by using, for example, deposition, photolithography, etc.

As illustrated in FIG. 11B, the first sub-dielectric layer 224A is formed on the active channel layer 122 by using, for example, deposition, etc. In an embodiment, the first sub-dielectric layer 224 may be planarized by using, for example, a CMP.

As illustrated in FIG. 11C, the first blocking layer 425 is formed over the first sub-dielectric layer 224A by using, for example, deposition, etc.

As illustrated in FIG. 11D, the second sub-dielectric layer 224B covering the first blocking layer 425 is formed by using, for example, deposition, etc. The second sub-dielectric layer 224B and the first sub-dielectric layer 224A may form the dielectric layer 224.

As illustrated in FIG. 11E, the dielectric layer 224 and the first blocking layer 425 in FIG. 11D are patterned to form the first through hole 224a and the second through hole 224b passing through the second sub-dielectric layer 224B, the first blocking layer 425 and the first sub-dielectric layer 224A and exposing the active channel layer 122 by using, for example, photolithography, etc.

As illustrated in FIG. 11F, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 400 in FIG. 4 is formed.

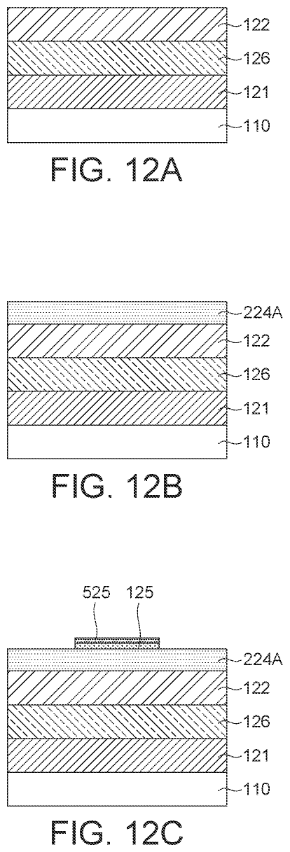

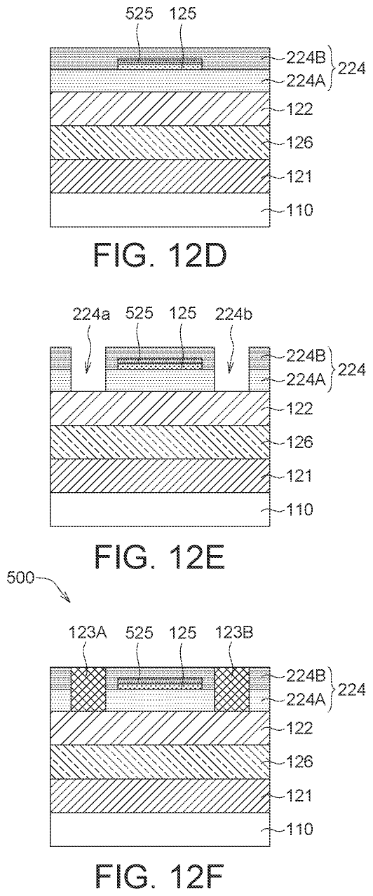

Referring to FIGS. 12A to 12F, FIGS. 12A to 12F illustrate schematic diagrams of manufacturing processes of the semiconductor device 500 in FIG. 5.

As illustrated in FIG. 12A, the back gate 121, the dielectric layer 126 and active channel layer 122 are formed on the FEOL structure 110 in order by using, for example, deposition, photolithography, etc.

As illustrated in FIG. 12B, the first sub-dielectric layer 224A is formed on the active channel layer 122 by using, for example, deposition, etc. In an embodiment, the first sub-dielectric layer 224A may be planarized by using, for example, a CMP.

As illustrated in FIG. 12C, the first blocking layer 125 is formed on the first sub-dielectric layer 224A by using, for example, deposition, photolithography, etc. Then, the second blocking layer 525 is formed on the first blocking layer 125 by using, for example, deposition, photolithography, etc.

As illustrated in FIG. 12D, the second sub-dielectric layer 224B covering the first blocking layer 125 and the second blocking layer 525 are formed by using, for example, deposition, etc. The second sub-dielectric layer 224B and the first sub-dielectric layer 224A may form the dielectric layer 224.

As illustrated in FIG. 12E, the dielectric layer 224 in FIG. 12D is patterned to form the first through hole 224a and the second through hole 224b passing through the second sub-dielectric layer 224B and the first sub-dielectric layer 224A and exposing the active channel layer 122 by using, for example, photolithography, etc.

As illustrated in FIG. 12F, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 500 in FIG. 5 is formed.

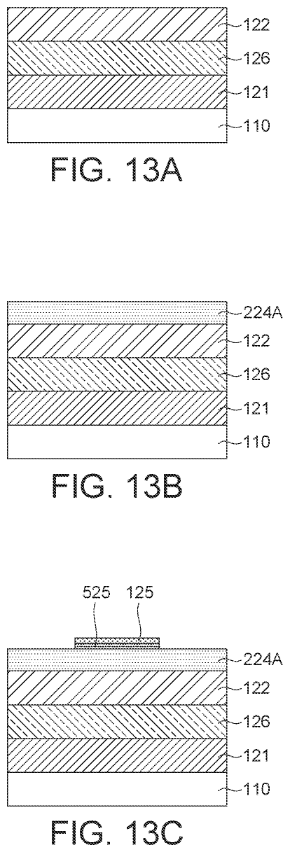

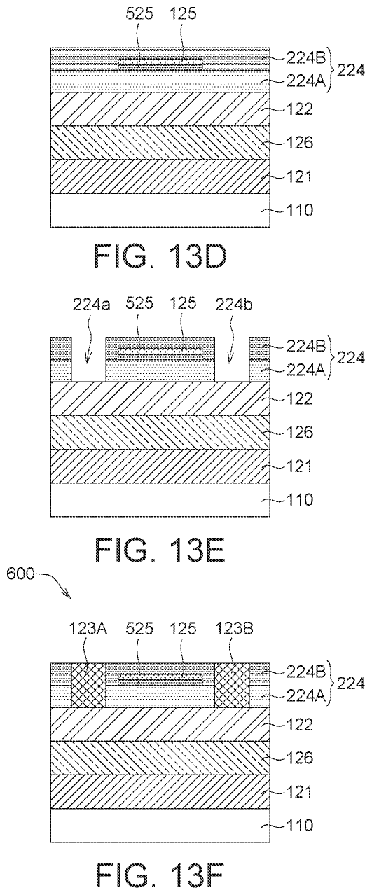

Referring to FIGS. 13A to 13F, FIGS. 13A to 13F illustrate schematic diagrams of manufacturing processes of the semiconductor device 600 in FIG. 6.

As illustrated in FIG. 13A, the back gate 121, the dielectric layer 126 and active channel layer 122 are formed on the FEOL structure 110 in order by using, for example, deposition, etc.

As illustrated in FIG. 13B, the first sub-dielectric layer 224A is formed on the active channel layer 122 by using, for example, deposition, etc. In an embodiment, the first sub-dielectric layer 224A may be planarized by using, for example, a CMP.

As illustrated in FIG. 13C, the second blocking layer 525 is formed on the first sub-dielectric layer 224A by using, for example, deposition, photolithography, etc. Then, the first blocking layer 125 is formed on the second blocking layer 525 by using, for example, deposition, etc.

As illustrated in FIG. 13D, the second sub-dielectric layer 224B covering the second blocking layer 525 and the first blocking layer 125 are formed by using, for example, deposition, etc. The second sub-dielectric layer 224B and the first sub-dielectric layer 224A may form the dielectric layer 224.

As illustrated in FIG. 13E, the dielectric layer 224 in FIG. 13D is patterned to form the first through hole 224a and the second through hole 224b passing through the second sub-dielectric layer 224B and the first sub-dielectric layer 224A and exposing the active channel layer 122 by using, for example, photolithography, etc.

As illustrated in FIG. 13F, the first electrode 123A and the second electrode 123B connected with the active channel layer 122 are formed within the first through hole 224a and the second through hole 224b respectively by using, for example, deposition, photolithography, etc. Then, the first electrode 123A, the second electrode 123B and the second sub-dielectric layer 224B may be planarized by using, for example, a CMP. So far, the semiconductor device 600 in FIG. 6 is formed.

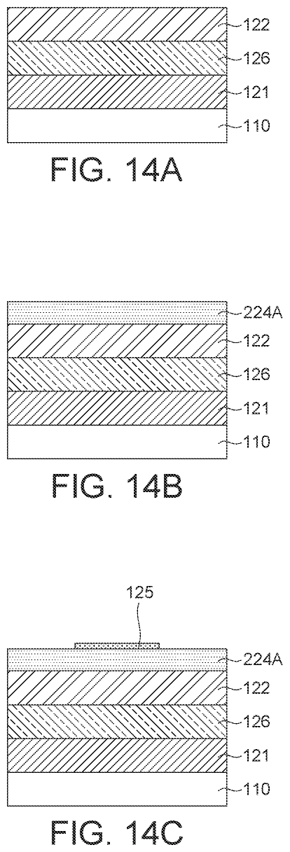

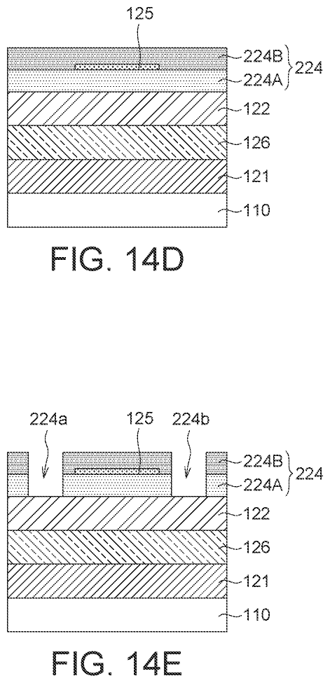

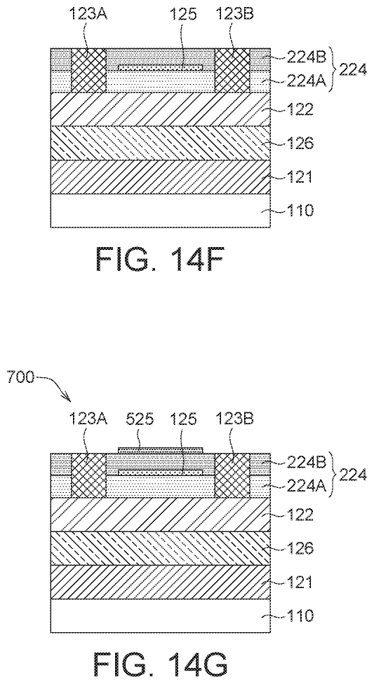

Referring to FIGS. 14A to 14G, FIGS. 14A to 14G illustrate schematic diagrams of manufacturing processes of the semiconductor device 700 in FIG. 7.

As illustrated in FIG. 14A, the back gate 121, the dielectric layer 126 and active channel layer 122 are formed on the FEOL structure 110 in order by using, for example, deposition, etc.

As illustrated in FIG. 14B, the first sub-dielectric layer 224A is formed on the active channel layer 122 by using, for example, deposition, etc. In an embodiment, the first sub-dielectric layer 224A may be planarized by using, for example, a CMP.

As illustrated in FIG. 14C, the first blocking layer 125 is formed on the first sub-dielectric layer 224A by using, for example, deposition, photolithography, etc.

As illustrated in FIG. 14D, the second sub-dielectric layer 224B covering the first blocking layer 125 is formed by using, for example, deposition, etc. The second sub-dielectric layer 224B and the first sub-dielectric layer 224A may form the dielectric layer 224.

As illustrated in FIG. 14E, the dielectric layer 224 in FIG. 14D is patterned to form the first through hole 224a and the second through hole 224b passing through the second sub-dielectric layer 224B and the first sub-dielectric layer 224A and exposing the active channel layer 122 by using, for example, photolithography, etc.

As illustrated in FIG. 14F, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP.

As illustrated in FIG. 14G, the second blocking layer 525 is formed on the second sub-dielectric layer 224B by using, for example, deposition, photolithography, etc. So far, the semiconductor device 700 in FIG. 7 is formed.

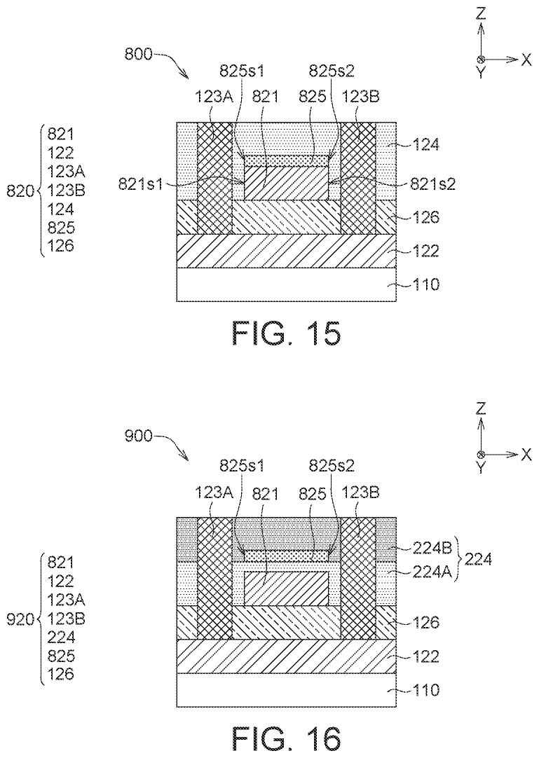

Referring to FIG. 15, FIG. 15 illustrates a schematic diagram of a cross-sectional view of a semiconductor device 800 according to an embodiment of the present disclosure. The semiconductor device 800 may include the FEOL structure 110 and at least one transistor 820. The transistor 820 is formed on the FEOL structure 110 and includes a top gate 821, the active channel layer 122, at least electrode (for example, a first electrode 123A and a second electrode 123B), the dielectric layer 124, a first blocking layer 825 and the dielectric layer 126. The top gate 821 is formed above the dielectric layer 126. The active channel layer 122 is formed between the FEOL structure 110 and the dielectric layer 126. The electrodes are electrically connected to the active channel layer 122. The dielectric layer 124 is formed over the dielectric layer 126. The first blocking layer 825 is formed in the dielectric layer 124 and overlaps the active channel layer 122 in the stacking direction (for example, Z-axis) of the first blocking layer 825 and the active channel layer 122. The first blocking layer 825 may block the gas and/or impurities from entering the active channel layer 122 in manufacturing process.

Referring to FIG. 15, the first blocking layer 825 may be formed of a material the same as or similar to that of the first blocking layer 125. In addition, the top gate 821 may be formed of a material the same as or similar to that of the back gate 121.

Referring to FIG. 15, the first blocking layer 825 has a first lateral surface 825s1 and a second lateral surface 825s2, and the top gate 821 has a first gate lateral surface 821s1 and a second gate lateral surface 821s2, wherein the first lateral surface 825s1 and the first gate lateral surface 821s1 are flushed with each other, and the second lateral surface 825s2 and the second gate lateral surface 821s2 are flushed with each other. In another embodiment, the first lateral surface 825s1 of the first blocking layer 825 may be spaced from the first gate lateral surface 821s1 by a distance in X-axis, and the second lateral surface 825s2 of the first blocking layer 825 may be spaced from the second gate lateral surface 821s2 by a distance in X-axis.

In another embodiment, the first blocking layer 825 may further cover at least one lateral surface of the top gate 821. In other embodiment, the first blocking layer 825 may be formed on an upper surface of the dielectric layer 124.

Referring to FIG. 16, FIG. 16 illustrates a schematic diagram of a cross-sectional view of a semiconductor device 900 according to an embodiment of the present disclosure. The semiconductor device 900 may include the FEOL structure 110 and at least one transistor 920. The transistor 920 is formed on the FEOL structure 110 and includes the top gate 821, the active channel layer 122, at least electrode (for example, a first electrode 123A and a second electrode 123B), the dielectric layer 224, first blocking layer 825 and the dielectric layer 126. The active channel layer 122 is formed between the FEOL structure 110 and the dielectric layer 126. The electrodes are electrically connected to the active channel layer 122. The dielectric layer 224 is formed over the dielectric layer 126. The first blocking layer 825 is formed in the dielectric layer 224 and overlaps the active channel layer 122 in the stacking direction (for example, Z-axis) of the first blocking layer 825 and the active channel layer 122. The first blocking layer 825 may block the gas and/or impurities from entering the active channel layer 122 in manufacturing process.

As illustrated in FIG. 16, the dielectric layer 224 is a multi-layered structure. Furthermore, the dielectric layer 224 includes the first sub-dielectric layer 224A and the second sub-dielectric layer 224B, wherein the first sub-dielectric layer 224A is formed on the dielectric layer 126, and the second sub-dielectric layer 224B is formed on the first sub-dielectric layer 224A. The first blocking layer 825 is formed in the second sub-dielectric layer 224B and over the first sub-dielectric layer 224A.

As illustrated in FIG. 16, the first blocking layer 825 has the first lateral surface 825s1 and the second lateral surface 825s2, wherein the first lateral surface 825s1 of the first blocking layer 825 may be spaced from the lateral surface of the first electrode 123A by a distance in X-axis, and the second lateral surface 825s2 of the first blocking layer 825 may be spaced from the lateral surface of the second electrode 123B by a distance in X-axis. In another embodiment, the first blocking layer 825 may be an insulation layer, wherein the first lateral surface 825s1 may be contact with the lateral surface of the first electrode 123A, and/or the second lateral surface 825s2 may be contact with the lateral surface of the second electrode 123B.

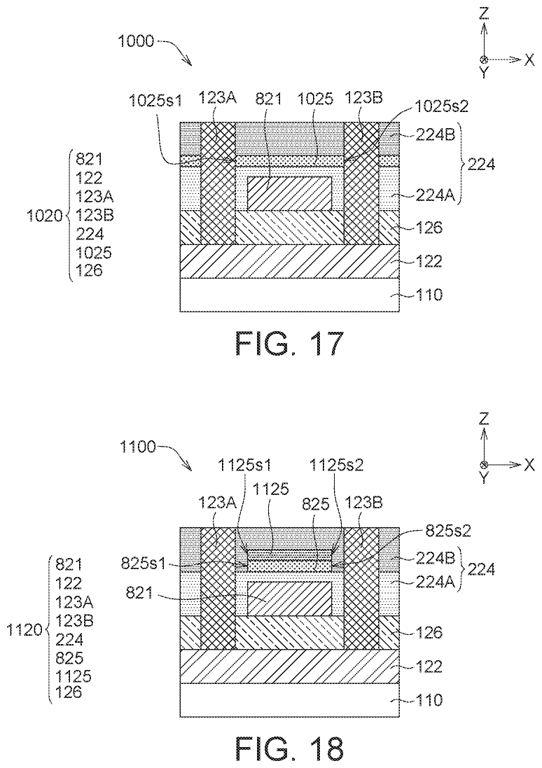

Referring to FIG. 17, FIG. 17 illustrates a schematic diagram of a cross-sectional view of a semiconductor device 1000 according to an embodiment of the present disclosure. The semiconductor device 1000 may include the FEOL structure 110 and at least one transistor 1020. The transistor 1020 is formed on the FEOL structure 110 and includes the top gate 821, the active channel layer 122, at least electrode (for example, a first electrode 123A and a second electrode 123B), the dielectric layer 224, first blocking layer 1025 and the dielectric layer 126. The active channel layer 122 is formed between the FEOL structure 110 and the dielectric layer 126. The electrodes are electrically connected to the active channel layer 122. The dielectric layer 224 is formed over the dielectric layer 126. The first blocking layer 1025 is formed in the dielectric layer 224 and overlaps the active channel layer 122 in the stacking direction (for example, Z-axis) of the first blocking layer 1025 and the active channel layer 122. The first blocking layer 1025 may block the gas and/or impurities from entering the active channel layer 122 in manufacturing process.

As illustrated in FIG. 17, the first blocking layer 1025 is formed within the dielectric layer 224. Furthermore, the first blocking layer 1025 is formed on the first sub-dielectric layer 224A and covered by the second sub-dielectric layer 224B. In the present embodiment, the first blocking layer 1025 may extend to the first electrode 123A and the second electrode 123B. Furthermore, the first blocking layer 1025 has a first lateral surface 1025s1 and a second lateral surface 1025s2, the first electrode 123A has the electrode lateral surface 123As, and the second electrode 123B has the electrode lateral surface 123Bs, wherein the first lateral surface 1025s1 is contact with the electrode lateral surface 123As, and the second lateral surface 1025s2 is contact with the electrode lateral surfaces 123Bs. As a result, most of the active channel layer 122 may be covered/protected by the first blocking layer 1025. In addition, the first blocking layer 1025 is formed within the dielectric layer 224. In the present embodiment, the first blocking layer 1025 may be formed of an insulation material including, for example, AlOx, NbOx, etc. As a result, the first blocking layer 1025 may electrically isolate the first electrode 123A from the second electrode 123B.

Referring to FIG. 18, FIG. 18 illustrates a schematic diagram of a cross-sectional view of a semiconductor device 1100 according to an embodiment of the present disclosure. The semiconductor device 1100 may include the FEOL structure 110 and at least one transistor 1120. The transistor 1120 is formed on the FEOL structure 110 and includes the top gate 821, the active channel layer 122, at least electrode (for example, a first electrode 123A and a second electrode 123B), the dielectric layer 224, first blocking layer 825, a second blocking layer 1125 and the dielectric layer 126. The active channel layer 122 is formed between the FEOL structure 110 and the dielectric layer 126. The electrodes are electrically connected to the active channel layer 122. The dielectric layer 224 is formed over the dielectric layer 126. The first blocking layer 825 and the second blocking layer 1125 are formed in the dielectric layer 224 and overlaps the active channel layer 122 in the stacking direction (for example, Z-axis) of the first blocking layer 825, the second blocking layer 1125 and the active channel layer 122. The first blocking layer 1025 may block the gas and/or impurities from entering the active channel layer 122 in manufacturing process.

As illustrated in FIG. 18, the dielectric layer 224 is a multi-layered structure. Furthermore, the dielectric layer 224 includes the first sub-dielectric layer 224A and the second sub-dielectric layer 224B. The first sub-dielectric layer 224A is formed on the dielectric layer 126, and the second sub-dielectric layer 224B is formed on the first sub-dielectric layer 224A. The first blocking layer 825 and the second blocking layer 1125 are formed between the first sub-dielectric layer 224A and the second sub-dielectric layer 224B. Furthermore, the first blocking layer 825 and the second blocking layer 1125 are formed above the first sub-dielectric layer 224A and covered by the second sub-dielectric layer 224B. In addition, the first blocking layer 825 is contact with the second blocking layer 1125.

As illustrated in FIG. 18, the first blocking layer 825 and the second blocking layer 1125 may be formed of different material. For example, the first blocking layer 825 may be formed of a high dielectric constant material including, for example, AlOx, HfOx, etc., and the second blocking layer 1125 may be formed of an oxide semiconductor material including, for example, CuO, SnO, InO, IZO, IGO, IGZO, IWO, IWZO, etc.

As illustrated in FIG. 18, in the present embodiment, the second blocking layer 1125 and the first blocking layer 825 overlap completely. In another embodiment, the second blocking layer 1125 may cover an upper surface and at least one lateral surface of the first blocking layer 825. In another embodiment, the second blocking layer 1125 overlaps a portion of an upper surface of the first blocking layer 825, and another portion of the upper surface of the first blocking layer 825 is exposed from the second blocking layer 1125.

As illustrated in FIG. 18, the first blocking layer 825 has the first lateral surface 825s1 and the second lateral surface 825s2, wherein the first lateral surface 825s1 of the first blocking layer 825 may be spaced from the lateral surface of the first electrode 123A by a distance in X-axis, and the second lateral surface 825s2 of the first blocking layer 825 may be spaced from the lateral surface of the second electrode 123B by a distance in X-axis. In another embodiment, the first blocking layer 825 may formed of an insulation material, wherein the first lateral surface 825s1 may be contact with the lateral surface of the first electrode 123A, and/or the second lateral surface 825s2 may be contact with the lateral surface of the second electrode 123B. The second blocking layer 1125 has a third lateral surface 1125s1 and a fourth second lateral surface 1125s2, wherein the third lateral surface 1125s1 of the second blocking layer 1125 may be spaced from the lateral surface of the first electrode 123A by a distance in X-axis, and the fourth lateral surface 1125s2 of the second blocking layer 1125 may be spaced from the lateral surface of the second electrode 123B by a distance in X-axis. In another embodiment, the second blocking layer 1125 may formed of an insulation material, wherein the third lateral surface 1125s1 may be contact with the lateral surface of the first electrode 123A, and/or the fourth lateral surface 1125s2 may be contact with the lateral surface of the second electrode 123B. In the present embodiment, the first lateral surface 825s1 may be aligned with the third lateral surface 1125s1, and the second lateral surface 825s2 may be aligned with the fourth lateral surface 1125s2. In another embodiment, the first lateral surface 825s1 may be spaced from the third lateral surface 1125s1 by a distance in X axis, and the second lateral surface 825s2 may be spaced from the fourth lateral surface 1125s2 by a distance in X axis.

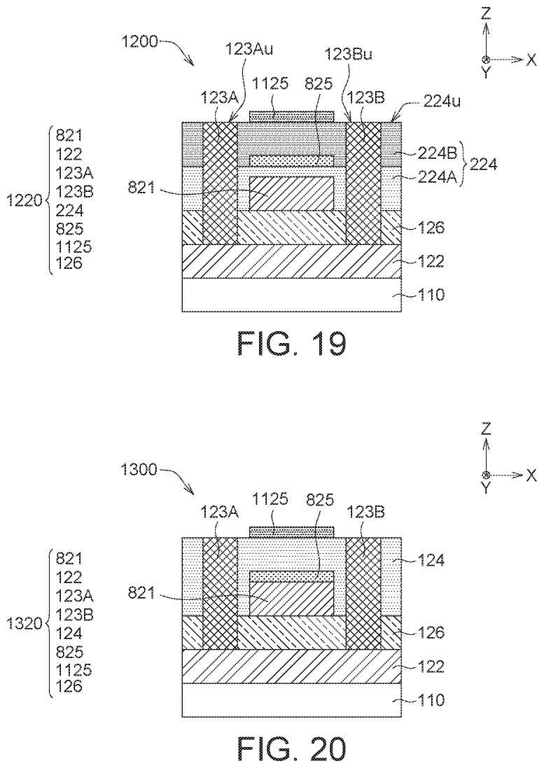

Referring to FIG. 19, FIG. 19 illustrates a schematic diagram of a cross-sectional view of a semiconductor device 1200 according to an embodiment of the present disclosure. The semiconductor device 1200 may include the FEOL structure 110 and at least one transistor 1220. The transistor 1220 is formed on the FEOL structure 110 and includes the top gate 821, the active channel layer 122, at least electrode (for example, a first electrode 123A and a second electrode 123B), the dielectric layer 224, first blocking layer 825, the second blocking layer 1125 and the dielectric layer 126. The active channel layer 122 is formed between the FEOL structure 110 and the dielectric layer 126. The electrodes are electrically connected to the active channel layer 122. The dielectric layer 224 is formed over the dielectric layer 126. The first blocking layer 825 is formed in the dielectric layer 224 and overlaps the active channel layer 122 in the stacking direction (for example, Z-axis) of the first blocking layer 825 and the active channel layer 122. The second blocking layer 1125 is formed over the dielectric layer 224 and overlaps the active channel layer 122 in the stacking direction (for example, Z-axis) of the second blocking layer 1125 and the active channel layer 122. The first blocking layer 825 and the second blocking layer 1125 may block the gas and/or impurities from entering the active channel layer 122 in manufacturing process.

As illustrated in FIG. 19, the dielectric layer 224 is a multi-layered structure. Furthermore, the dielectric layer 224 includes the first sub-dielectric layer 224A and the second sub-dielectric layer 224B. The first sub-dielectric layer 224A is formed on the dielectric layer 126, and the second sub-dielectric layer 224B is formed on the first sub-dielectric layer 224A. The dielectric layer 224 has the first upper surface 224u, the first electrode 123A has the second upper surface 123Au, and the second electrode 123B has the second upper surface 123Bu, wherein the first upper surface 224u, the second upper surface 123Au and the second upper surface 123Bu are flush with each other. One of the first blocking layer 825 and the second blocking layer 1125 may be formed on the first upper surface 224u.

In the present embodiment, the first blocking layer 825 is formed on the first sub-dielectric layer 224A, and the second blocking layer 1125 is formed on the second sub-dielectric layer 224B. The first blocking layer 825 and the second blocking layer 1125 may be separated from each other by the second sub-dielectric layer 224B.

Referring to FIG. 20, FIG. 20 illustrates a schematic diagram of a cross-sectional view of a semiconductor device 1300 according to an embodiment of the present disclosure. The semiconductor device 1300 may include the FEOL structure 110 and at least one transistor 1320. The transistor 1320 is formed on the FEOL structure 110 and includes the top gate 821, the active channel layer 122, at least electrode (for example, a first electrode 123A and a second electrode 123B), the dielectric layer 124, first blocking layer 825, the second blocking layer 1125 and the dielectric layer 126. The active channel layer 122 is formed between the FEOL structure 110 and the dielectric layer 126. The electrodes are electrically connected to the active channel layer 122. The dielectric layer 124 is formed over the dielectric layer 126. The first blocking layer 825 is formed within the dielectric layer 124 and overlaps the active channel layer 122 in the stacking direction (for example, Z-axis) of the first blocking layer 825 and the active channel layer 122. The second blocking layer 1125 is formed over the dielectric layer 124 and overlaps the active channel layer 122 in the stacking direction (for example, Z-axis) of the second blocking layer 1125 and the active channel layer 122. The first blocking layer 825 and the second blocking layer 1125 may block the gas and/or impurities from entering the active channel layer 122 in manufacturing process.

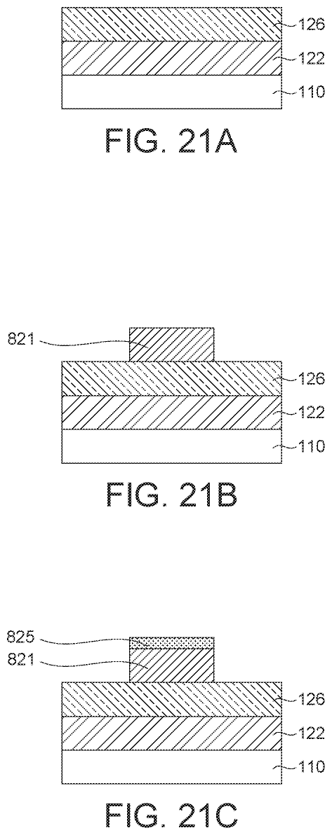

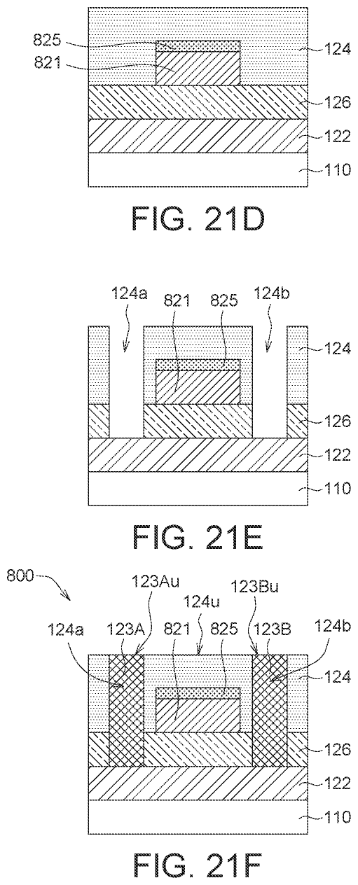

Referring to FIGS. 21A to 21F, FIGS. 21A to 21F illustrate schematic diagrams of manufacturing processes of the semiconductor device 800 in FIG. 15.

As illustrated in FIG. 21A, the active channel layer 122 and the dielectric layer 126 are formed on the FEOL structure 110 in order by using, for example, deposition, etc.

As illustrated in FIG. 21B, the top gate 821 is formed on the dielectric layer 126 by using, for example, deposition, photolithography, etc.

As illustrated in FIG. 21C, the first blocking layer 825 is formed on the top gate 821 by using, for example, photolithography, etc.

As illustrated in FIG. 21D, the dielectric layer 124 covering the top gate 821 and the first blocking layer 825 is formed on the dielectric layer 126 by using, for example, deposition, etc.

As illustrated in FIG. 21E, the dielectric layer 124 and the dielectric layer 126 in FIG. 21D are patterned to form the first through hole 124a and the second through hole 124b passing the dielectric layer 124 and the dielectric layer 126 and exposing the active channel layer 122 by using, for example, photolithography, etc.

As illustrated in FIG. 21F, the first electrode 123A and the second electrode 123B connected with the active channel layer 122 are formed within the first through hole 124a and the second through hole 124b respectively by using, for example, deposition, electroplating, etc. Then, the first electrode 123A, the second electrode 123B and the dielectric layer 124 may be planarized by using, for example, a CMP. After CMP, the first electrode 123A has the second upper surface 123Au, the second electrode 123B has the second upper surface 123Bu and the dielectric layer 124 has the first upper surface 124u, wherein the second upper surface 123Au, the second upper surface 123Bu and the first upper surface 124u are flushed with each other. So far, the semiconductor device 800 in FIG. 15 is formed.

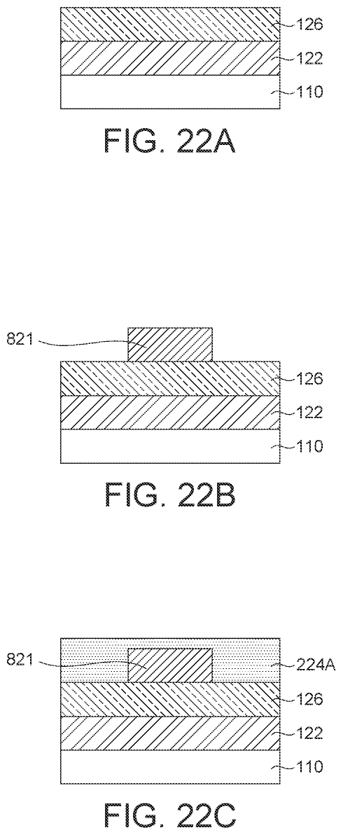

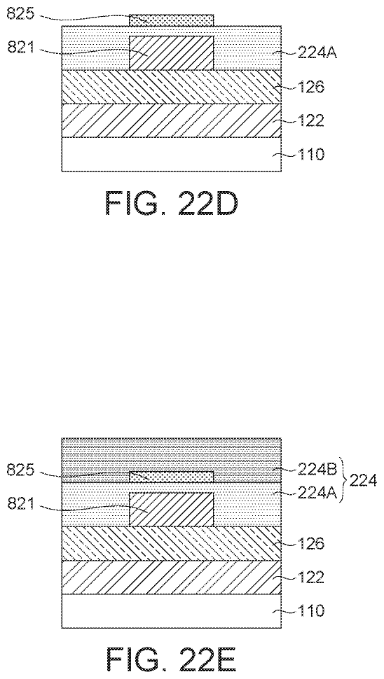

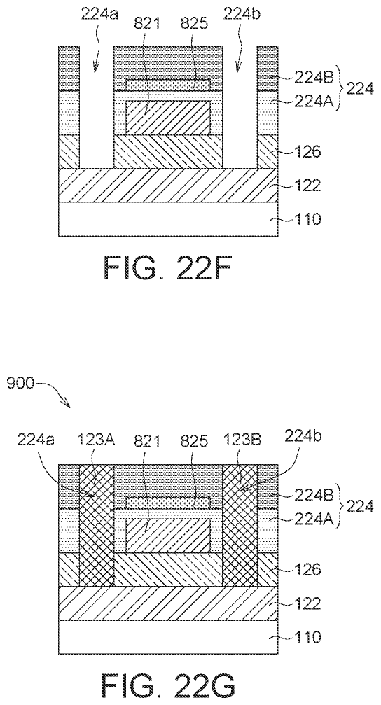

Referring to FIGS. 22A to 22G, FIGS. 22A to 22G illustrate schematic diagrams of manufacturing processes of the semiconductor device 900 in FIG. 16.

As illustrated in FIG. 22A, the active channel layer 122 and the dielectric layer 126 are formed on the FEOL structure 110 in order by using, for example, deposition, etc.

As illustrated in FIG. 22B, the top gate 821 is formed on the dielectric layer 126 by using, for example, deposition, photolithography, etc.

As illustrated in FIG. 22C, the first sub-dielectric layer 224A covering the top gate 821 is formed on the dielectric layer 126 by using, for example, deposition, etc. In an embodiment, the first sub-dielectric layer 224A may be planarized by using, for example, a CMP.

As illustrated in FIG. 22D, the first blocking layer 825 is formed on the first sub-dielectric layer 224A by using, for example, deposition, photolithography, etc.

As illustrated in FIG. 22E, the second sub-dielectric layer 224B covering the first blocking layer 825 is formed on the first sub-dielectric layer 224A by using, for example, deposition, etc. The second sub-dielectric layer 224B and the first sub-dielectric layer 224A may form the dielectric layer 224.

As illustrated in FIG. 22F, the dielectric layer 224 and the dielectric layer 126 in FIG. 22E are patterned to form the first through hole 224a and the second through hole 224b passing through the second sub-dielectric layer 224B, the first sub-dielectric layer 224A and the dielectric layer 126 and exposing the active channel layer 122 by using, for example, photolithography, etc.

As illustrated in FIG. 22G, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 900 in FIG. 16 is formed.

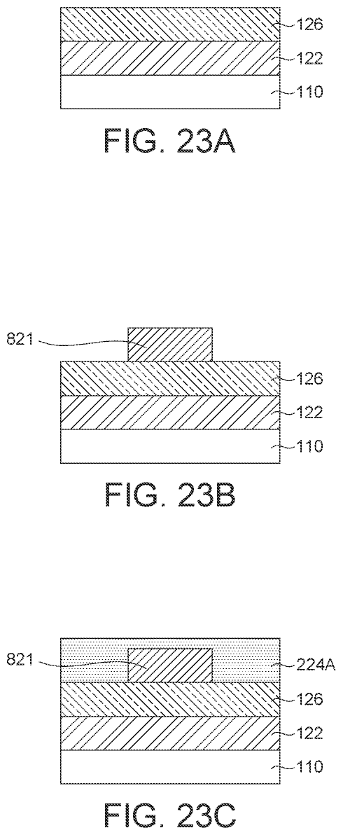

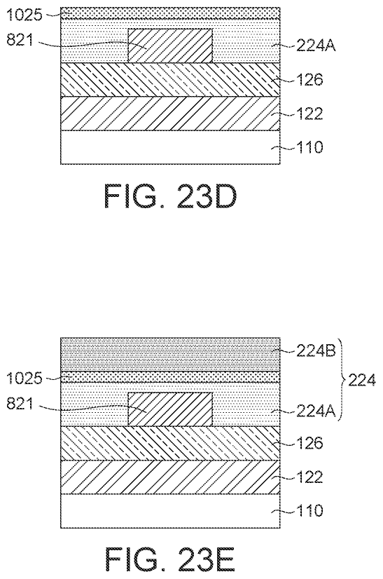

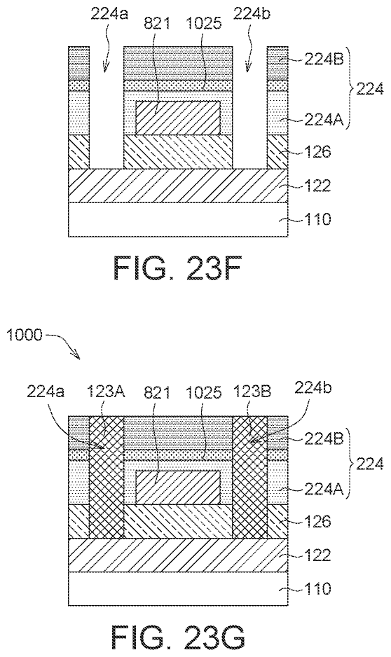

Referring to FIGS. 23A to 23G, FIGS. 23A to 23G illustrate schematic diagrams of manufacturing processes of the semiconductor device 1000 in FIG. 17.

As illustrated in FIG. 23A, the active channel layer 122 and the dielectric layer 126 are formed on the FEOL structure 110 in order by using, for example, deposition, etc.

As illustrated in FIG. 23B, the top gate 821 is formed on the dielectric layer 126 by using, for example, deposition, photolithography, etc.

As illustrated in FIG. 23C, the first sub-dielectric layer 224A covering the top gate 821 is formed on the dielectric layer 126 by using, for example, deposition, etc. In an embodiment, the first sub-dielectric layer 224A may be planarized by using, for example, a CMP.

As illustrated in FIG. 23D, the first blocking layer 1025 is formed over the first sub-dielectric layer 224A by using, for example, deposition, etc.

As illustrated in FIG. 23E, the second sub-dielectric layer 224B covering the first blocking layer 1025 is formed by using, for example, deposition, etc. The second sub-dielectric layer 224B and the first sub-dielectric layer 224A may form the dielectric layer 224.

As illustrated in FIG. 23F, the dielectric layer 224, the first blocking layer 1025 and the dielectric layer 126 in FIG. 23E are patterned to form the first through hole 224a and the second through hole 224b passing through the second sub-dielectric layer 224B, the first blocking layer 1025, the first sub-dielectric layer 224A and the dielectric layer 126 and exposing the active channel layer 122 by using, for example, photolithography, etc.

As illustrated in FIG. 23G, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 1000 in FIG. 17 is formed.

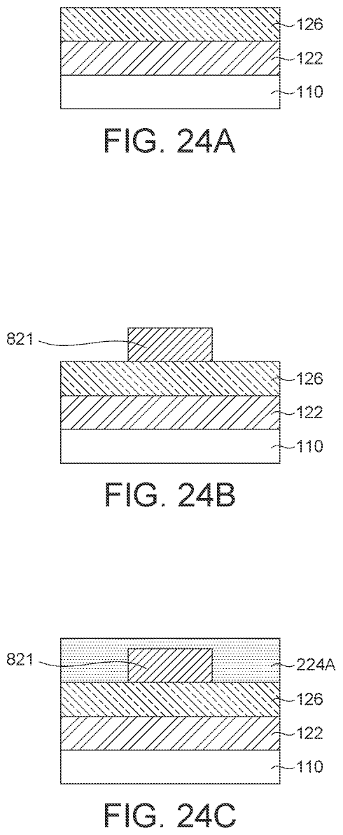

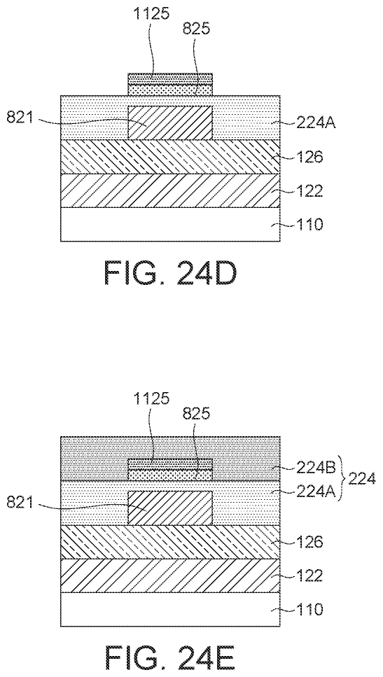

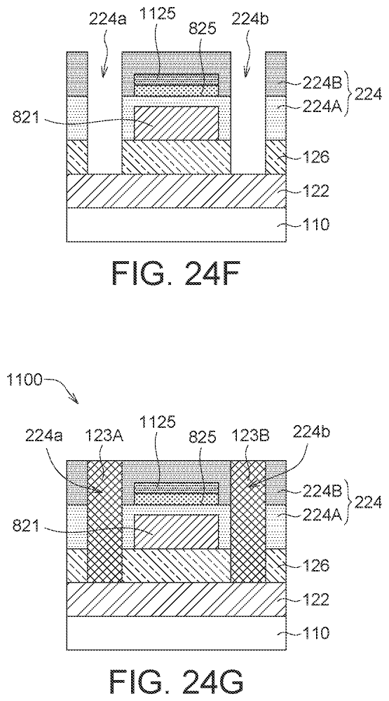

Referring to FIGS. 24A to 24G, FIGS. 24A to 24G illustrate schematic diagrams of manufacturing processes of the semiconductor device 1100 in FIG. 18.

As illustrated in FIG. 24A, the active channel layer 122 and the dielectric layer 126 are formed on the FEOL structure 110 in order by using, for example, deposition, etc.

As illustrated in FIG. 24B, the top gate 821 is formed on the dielectric layer 126 by using, for example, deposition, photolithography, etc.

As illustrated in FIG. 24C, the first sub-dielectric layer 224A covering the top gate 821 is formed on the dielectric layer 126 by using, for example, deposition, etc. In an embodiment, the first sub-dielectric layer 224A may be planarized by using, for example, a CMP.

As illustrated in FIG. 24D, the first blocking layer 825 is formed on the first sub-dielectric layer 224A by using, for example, deposition, photolithography, etc. Then, the second blocking layer 1125 is formed on the first blocking layer 825 by using, for example, deposition, photolithography, etc.

As illustrated in FIG. 24E, the second sub-dielectric layer 224B covering the first blocking layer 825 and the second blocking layer 1125 are formed by using, for example, deposition, etc. The second sub-dielectric layer 224B and the first sub-dielectric layer 224A may form the dielectric layer 224.

As illustrated in FIG. 24F, the dielectric layer 224 and the dielectric layer 126 in FIG. 22E are patterned to form the first through hole 224a and the second through hole 224b passing through the second sub-dielectric layer 224B, the first sub-dielectric layer 224A and the dielectric layer 126 and exposing the active channel layer 122 by using, for example, photolithography, etc.

As illustrated in FIG. 24G, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 1100 in FIG. 18 is formed.

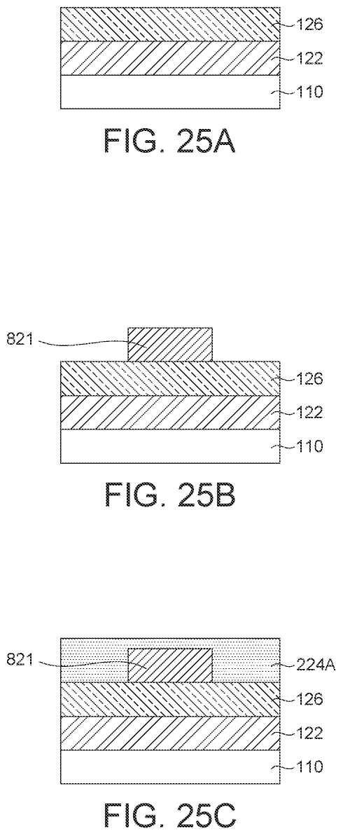

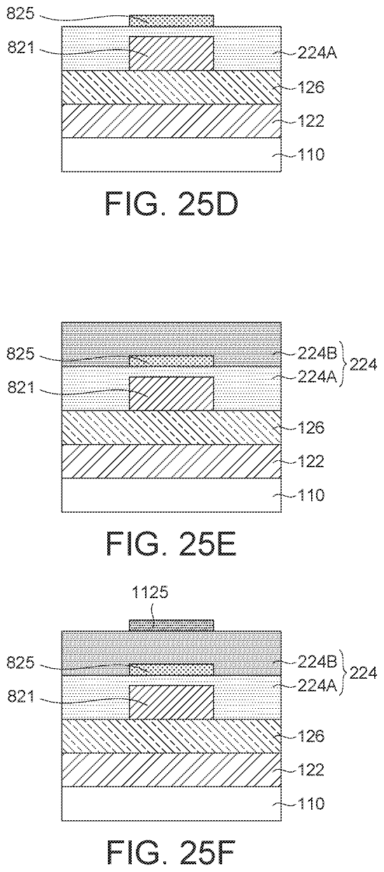

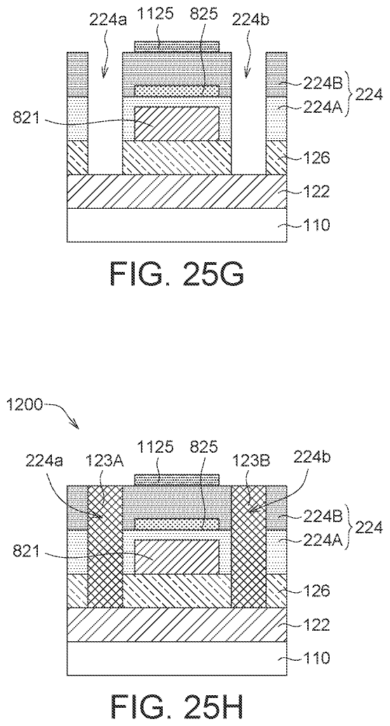

Referring to FIGS. 25A to 24H, FIGS. 25A to 25H illustrate schematic diagrams of manufacturing processes of the semiconductor device 1200 in FIG. 19.

As illustrated in FIG. 25A, the active channel layer 122 and the dielectric layer 126 are formed on the FEOL structure 110 in order by using, for example, deposition, etc.

As illustrated in FIG. 25B, the top gate 821 is formed on the dielectric layer 126 by using, for example, deposition, photolithography, etc.

As illustrated in FIG. 25C, the first sub-dielectric layer 224A covering the top gate 821 is formed on the dielectric layer 126 by using, for example, deposition, etc. In an embodiment, the first sub-dielectric layer 224A may be planarized by using, for example, a CMP.

As illustrated in FIG. 25D, the first blocking layer 825 is formed on the first sub-dielectric layer 224A by using, for example, deposition, photolithography, etc.

As illustrated in FIG. 25E, the second sub-dielectric layer 224B covering the first blocking layer 825 is formed on the first sub-dielectric layer 224A by using, for example, deposition, etc. The second sub-dielectric layer 224B and the first sub-dielectric layer 224A may form the dielectric layer 224. In an embodiment, the second sub-dielectric layer 224B may be planarized by using, for example, a CMP.

As illustrated in FIG. 25F, the second blocking layer 1125 is formed on the second sub-dielectric layer 224B by using, for example, deposition, photolithography, etc.

As illustrated in FIG. 25G, the dielectric layer 224 and the dielectric layer 126 in FIG. 22E are patterned to form the first through hole 224a and the second through hole 224b passing through the second sub-dielectric layer 224B, the first sub-dielectric layer 224A and the dielectric layer 126 and exposing the active channel layer 122 by using, for example, photolithography, etc.

As illustrated in FIG. 25H, the first electrode 123A and the second electrode 123B connected with the active channel layer 122 are formed within the first through hole 224a and the second through hole 224b respectively by using, for example, deposition, electroplating, etc. Then, the first electrode 123A, the second electrode 123B and the second sub-dielectric layer 224B may be planarized by using, for example, a CMP. So far, the semiconductor device 1200 in FIG. 19 is formed.

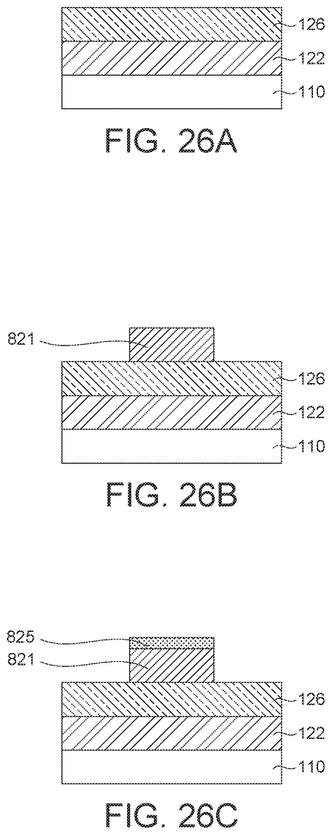

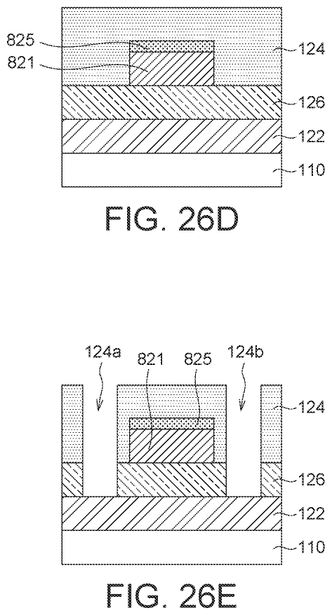

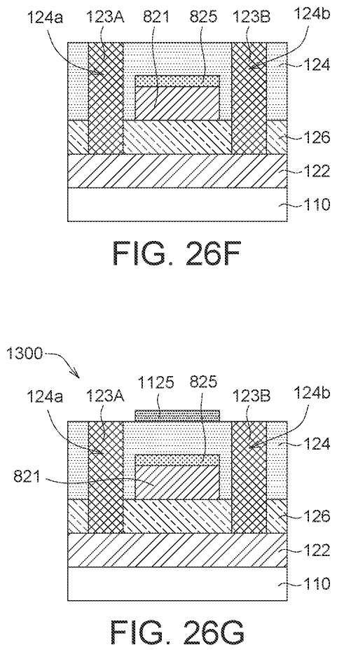

Referring to FIGS. 26A to 26G, FIGS. 26A to 26G illustrate schematic diagrams of manufacturing processes of the semiconductor device 1300 in FIG. 20.

As illustrated in FIG. 26A, the active channel layer 122 and the dielectric layer 126 are formed on the FEOL structure 110 in order by using, for example, deposition, etc.

As illustrated in FIG. 26B, the top gate 821 is formed on the dielectric layer 126 by using, for example, deposition, photolithography, etc.

As illustrated in FIG. 26C, the first blocking layer 825 is formed on the top gate 821 by using, for example, deposition, photolithography, etc.

As illustrated in FIG. 26D, the dielectric layer 124 covering the top gate 821 and the first blocking layer 825 is formed on the dielectric layer 126 by using, for example, deposition, etc.

As illustrated in FIG. 26E, the dielectric layer 124 and the dielectric layer 126 in FIG. 26D are patterned to form the first through hole 124a and the second through hole 124b passing the dielectric layer 124 and the dielectric layer 126 and exposing the active channel layer 122 by using, for example, photolithography, etc.

As illustrated in FIG. 26F, the first electrode 123A and the second electrode 123B connected with the active channel layer 122 are formed within the first through hole 124a and the second through hole 124b respectively by using, for example, deposition, electroplating, etc. Then, the first electrode 123A, the second electrode 123B and the dielectric layer 124 may be planarized by using, for example, a CMP.

As illustrated in FIG. 26G, the second blocking layer 1125 is formed on the dielectric layer 124 by using, for example, deposition, photolithography, etc. So far, the semiconductor device 1300 in FIG. 20 is formed.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a transistor at least including an active channel layer and a blocking layer, wherein the blocking layer overlaps the active channel layer. Accordingly, the blocking layer may block the gas and/or impurities from entering the active channel layer in manufacturing process.

Example embodiment 1: a semiconductor device includes a FEOL structure and a transistor. The transistor is disposed on the FEOL structure and includes a back gate, an active channel layer, an electrode, a dielectric layer and a first blocking layer. The back gate is disposed on the FEOL structure. The active channel layer is disposed on the back gate. The electrode electrically is connected to the active channel layer. The dielectric layer is disposed above the active channel layer. The first blocking layer is disposed on the dielectric layer and overlaps the active channel layer.

Example embodiment 2: the dielectric layer includes a first sub-dielectric layer and a second sub-dielectric layer. The first sub-dielectric layer is disposed on the active channel layer. The second sub-dielectric layer is disposed on the first sub-dielectric layer and covers the first blocking layer. The first blocking layer is disposed between the first sub-dielectric layer and the second sub-dielectric layer.

Example embodiment 3: the dielectric layer has a first upper surface, the electrode has a second upper surface, and the first upper surface and the second upper surface are flush with each other; the first blocking layer is disposed over the first upper surface.

Example embodiment 4: the first blocking layer has a lateral surface, and the lateral surface and the electrode are spaced from each other.

Example embodiment 5: the first blocking layer is formed of a conductive material.

Example embodiment 6: the first blocking layer has a first lateral surface, the electrode has a second lateral surface, and the first lateral surface is contact with the second lateral surface.

Example embodiment 7: the first blocking layer is formed of an insulation material.

Example embodiment 8: the transistor further includes a second blocking layer overlapping the first blocking layer.

Example embodiment 9: a semiconductor device includes a FEOL structure and a transistor. The BEOL structure is disposed on the FEOL structure and includes a top gate, an active channel layer, an electrode, a dielectric layer and a first blocking layer. The top gate disposed on the FEOL structure. The active channel layer disposed on the FEOL structure. The electrode electrically is connected to the active channel layer. The first blocking layer is disposed over the active channel layer.

Example embodiment 10: the dielectric layer includes a first sub-dielectric layer and a second sub-dielectric layer. The second sub-dielectric layer is disposed on the first sub-dielectric layer. The first blocking layer and the second sub-dielectric layer are disposed between the first sub-dielectric layer and the second sub-dielectric layer.

Example embodiment 11: the dielectric layer has a first upper surface, the electrode has a second upper surface, and the first upper surface and the second upper surface are flush with each other; one of the first blocking layer and the second blocking layer is disposed on the first upper surface.

Example embodiment 12: the first blocking layer has a lateral surface, and the lateral surface and the electrode are spaced from each other.

Example embodiment 13: the first blocking layer is formed of a conductive material.

Example embodiment 14: the first blocking layer has a first lateral surface, the electrode has a second lateral surface, and the first lateral surface is contact with the second lateral surface.

Example embodiment 15: the first blocking layer is formed of an insulation material.

Example embodiment 16: the first blocking layer is contact with the second blocking layer.

Example embodiment 17: a manufacturing method for a semiconductor device includes the following steps: forming a FEOL structure; forming a transistor, includes: forming a back gate on the FEOL structure; forming an active channel layer on the back gate; forming a dielectric layer over the active channel layer; forming a first blocking layer on the dielectric layer, wherein the first blocking layer overlaps the active channel layer; and forming an electrode electrically connected to the active channel layer.

Example embodiment 18: forming the dielectric layer over the active channel includes: forming a first sub-dielectric layer on the active channel layer. Forming the first blocking layer on the dielectric layer includes: forming the first blocking layer over the first sub-dielectric layer. The forming the dielectric layer over the active channel includes: forming the second sub-dielectric layer on the first sub-dielectric layer, wherein the second sub-dielectric layer covers the first blocking layer.

Example embodiment 19: in forming the electrode electrically connected to the active channel layer, the first blocking layer has a lateral surface, and the lateral surface and the electrode are spaced from each other.

Example embodiment 21: in forming the electrode electrically connected to the active channel layer, the first blocking layer has a first lateral surface, the electrode has a second lateral surface, and the first lateral surface is contact with the second lateral surface; in forming the first blocking layer in the dielectric layer, the first blocking layer is formed of an insulation material.

Example embodiment 21: in forming the first blocking layer in the dielectric layer, the first blocking layer is formed of a conductive material.

Example embodiment 22: one of the first blocking layer and the second blocking layer is disposed above another of the first blocking layer and the second blocking layer.

Example embodiment 23: one of the first blocking layer and the second blocking layer covers an upper surface and/or a lateral surface of another of the first blocking layer and the second blocking layer.

Example embodiment 24: the first blocking layer overlaps at least one portion of the active channel layer in a stacking direction of the first blocking layer and the active channel layer or a thickness direction of the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a FEOL (Front End of Line) structure;
a transistor on the FEOL structure and comprising:
a back gate on the FEOL structure;
an active channel layer on the back gate;
an electrode electrically connected to the active channel layer;
a dielectric layer above the active channel layer; and
a first blocking layer disposed on the dielectric layer and overlapping the active channel layer.

2. The semiconductor device as claimed in claim 1, wherein the dielectric layer comprises:
a first sub-dielectric layer on the active channel layer; and
a second sub-dielectric layer on the first sub-dielectric layer and covering the first blocking layer;
wherein the first blocking layer is disposed between the first sub-dielectric layer and the second sub-dielectric layer.

3. The semiconductor device as claimed in claim 1, wherein the dielectric layer has a first upper surface, the electrode has a second upper surface, and the first upper surface and the second upper surface are flush with each other; the first blocking layer is disposed over the first upper surface.

4. The semiconductor device as claimed in claim 1, wherein the first blocking layer has a lateral surface, and the lateral surface and the electrode are spaced from each other.

5. The semiconductor device as claimed in claim 4, wherein the first blocking layer is formed of a conductive material.

6. The semiconductor device as claimed in claim 1, wherein the first blocking layer has a first lateral surface, the electrode has a second lateral surface, and the first lateral surface is contact with the second lateral surface.

7. The semiconductor device as claimed in claim 6, wherein the first blocking layer is formed of an insulation material.

8. The semiconductor device as claimed in claim 6, wherein the transistor further comprises:
a second blocking layer overlapping the first blocking layer.

9. A semiconductor device, comprising:
a FEOL structure;
a transistor on the FEOL structure and comprising:
a top gate on the FEOL structure;
an active channel layer on the FEOL structure;
a dielectric layer above the active channel layer and covering the top gate;
an electrode electrically connected to the active channel layer;
a first blocking layer over the active channel layer.

10. The semiconductor device as claimed in claim 9, wherein the dielectric layer comprises:
a first sub-dielectric layer; and
a second sub-dielectric layer on the first sub-dielectric layer;
wherein the first blocking layer and the second sub-dielectric layer are disposed between the first sub-dielectric layer and the second sub-dielectric layer.

11. The semiconductor device as claimed in claim 9, wherein the dielectric layer has a first upper surface, the electrode has a second upper surface, and the first upper surface and the second upper surface are flush with each other; one of the first blocking layer and the second blocking layer is disposed on the first upper surface.

12. The semiconductor device as claimed in claim 9, wherein the first blocking layer has a lateral surface, and the lateral surface and the electrode are spaced from each other.

13. The semiconductor device as claimed in claim 12, wherein the first blocking layer is formed of a conductive material.

14. The semiconductor device as claimed in claim 9, wherein the first blocking layer has a first lateral surface, the electrode has a second lateral surface, and the first lateral surface is contact with the second lateral surface.

15. The semiconductor device as claimed in claim 14, wherein the first blocking layer is formed of an insulation material.

16. The semiconductor device as claimed in claim 9, wherein the first blocking layer is contact with the second blocking layer.

17. A manufacturing method for a semiconductor device, comprising:
forming a FEOL structure;
forming a transistor, comprising:
forming a back gate on the FEOL structure;
forming an active channel layer on the back gate;
forming a dielectric layer over the active channel layer;
forming a first blocking layer on the dielectric layer, wherein the first blocking layer overlaps the active channel layer; and
forming an electrode electrically connected to the active channel layer.

18. The manufacturing method as claimed in claim 17, wherein forming the dielectric layer over the active channel layer comprises:
forming a first sub-dielectric layer on the active channel layer;
wherein forming the first blocking layer on the dielectric layer comprises:
forming the first blocking layer over the first sub-dielectric layer;
wherein forming the dielectric layer over the active channel comprises:
forming the second sub-dielectric layer on the first sub-dielectric layer, wherein the second sub-dielectric layer covers the first blocking layer.

19. The manufacturing method as claimed in claim 17, wherein in forming the electrode electrically connected to the active channel layer, the first blocking layer has a lateral surface, and the lateral surface and the electrode are spaced from each other.

20. The manufacturing method as claimed in claim 17, wherein in forming the electrode electrically connected to the active channel layer, the first blocking layer has a first lateral surface, the electrode has a second lateral surface, and the first lateral surface is contact with the second lateral surface; in forming the first blocking layer in the dielectric layer, the first blocking layer is formed of an insulation material.
